(19) United States
(12) Patent Application Publication
(10) Pub. No.: US 2023/0097238 A1
(43) Pub. Date: Mar. 30, 2023

(54) ORGANIC EL DISPLAY DEVICE AND PHOTOSENSITIVE RESIN COMPOSITION

(71) Applicant: TORAY INDUSTRIES, INC., Tokyo (JP)

(72) Inventors: Ryosuke AIHARA, Otsu-shi (JP); Takashi HONMA, Otsu-shi (JP); Akihiro ISHIKAWA, Otsu-shi (JP)

(73) Assignee: TORAY INDUSTRIES, INC., Tokyo (JP)

(21) Appl. No.: 17/908,344

(22) PCT Filed: Mar. 10, 2021
(86) PCT No.: PCT/JP2021/009466

§ 371 Date: Aug. 31, 2022

(30) Foreign Application Priority Data
Mar. 13, 2020 (JP) 2020-043994

(51) Int. Cl. H10K 59/122; H10K 59/38; H10K 50/86; G03F 7/039; G03F 7/004

(52) U.S. Cl. CPC H01L 27/3246; H01L 27/322; H01L 51/5284; G03F 7/0392; G03F 7/0048; G03F 7/0042

(57) ABSTRACT

An organic EL display device including a substrate, and a planarization layer, a first electrode, a pixel division layer, a light emitting pixel and a second electrode formed on the substrate, wherein the planarization layer and/or the pixel division layer contain(s) zirconium nitride particles, and a crystallite size of the zirconium nitride particles determined from a half width of a peak derived from a (111) plane in an X-ray diffraction spectrum using a CuKα ray as an X-ray source is 5 nm or more 20 nm or less. Provided are an organic EL display device with excellent visibility and fewer display defects, and a cured film which is excellent in storage stability of a photosensitive resin composition capable of being applied on an insulating layer of the organic EL display device, and which has high sensitivity and high visible light-shielding property and is also free from residue in the opening.

### TECHNICAL FIELD

The present invention relates to an organic EL display device and a photosensitive resin composition.

### BACKGROUND ART

In recent years, there have been developed many products using organic electroluminescence (hereinafter referred to as “EL”) display devices in thin display devices such as smartphones, tablet PCs and televisions.

An organic EL display device is a self-luminous display device that emits light using energy induced by recombination of electrons injected from a cathode and electron holes injected from an anode. Therefore, if a substance which inhibits the movement of electrons or electron holes and a substance which forms an energy level that inhibits the recombination of electrons and electron holes are present in a light emitting layer, these substances have an influence on reduction in luminous efficiency of a light emitting element or deactivation of a light emitting material, leading to a decrease in lifetime of the light emitting element. Degassing and outflow of ionic components from a pixel division layer formed at a position adjacent to the light emitting layer may cause a decrease in lifetime of the organic EL display device. Therefore, there is disclosed a technique using, as a resin composition for forming a pixel division layer, a positive photosensitive polyimide resin composition having excellent heat resistance and reliability (see, for example, Patent Document 1).

In recent years, attempts have been made to improve the visibility and contrast of the organic EL display device by imparting the light-shielding property to the pixel division layer to reduce the reflection of external light such as sunlight. There are disclosed, as specific examples thereof, an organic EL display device including a pixel division layer using a positive photosensitive resin composition containing carbon black (see, for example, Patent Document 2) and a positive photosensitive resin composition using a zirconium nitride compound (see, for example, Patent Document 3).

### PRIOR ART DOCUMENTS

### Patent Documents

Patent Document 1: JP 2002-91343 A
Patent Document 2: JP 2013-533508 A
Patent Document 3: WO 2019-059359

### SUMMARY OF THE INVENTION

### Problems to be Solved by the Invention

However, in the organic EL display device including a cured film of the resin composition as mentioned in Patent Document 3 in a planarization layer or a pixel division layer, there was a problem that a short circuit between a first electrode and a second electrode originates from coarse particles in the planarization layer or pixel division layer, and thus some pixels reach a state of off-pixel, and that local non-light emitting sites derived from the development residue of the pigment aggregate is generated.

An object of the present invention is to solve the above-mentioned problems to obtain an organic EL display device which is free from off-pixel and has excellent visibility.

### Solutions to the Problems

The present invention is directed to an organic EL display device including a substrate, and a planarization layer, a first electrode, a pixel division layer, a light emitting pixel and a second electrode formed on the substrate, wherein the planarization layer and/or the pixel division layer contain(s) zirconium nitride particles (A), and a crystallite size of the zirconium nitride particles (A) determined from a half width of a peak derived from a (111) plane in an X-ray diffraction spectrum using a CuKα ray as an X-ray source is 5 nm or more 20 nm or less.

The present invention is also directed to a photosensitive resin composition including zirconium nitride particles (A), an alkaline soluble resin (B) including a repeating structural unit represented by general formula (1) shown below and/or a repeating structural unit represented by the following general formula (2), an organic solvent (C) and a photoacid generator (D), wherein an acid equivalent of the alkaline soluble resin (B) is 200 g/mol or more and 500 g/mol or less:

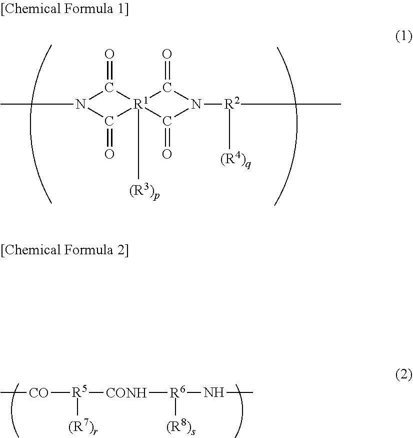

wherein, in general formula (1), R¹ represents a tetra- to decavalent organic group having 5 to 40 carbon atoms, R² represents a di- to octavalent organic group having 5 to 40 carbon atoms; R³ and R⁴ each independently represent a hydroxyl group, a carboxy group, a sulfonic acid group or a thiol group; and p and q represent an integer of 0 to 6 and p+q>0; and
wherein, in general formula (2), R⁵ represents a di- to octavalent organic group having 5 to 40 carbon atoms, R⁶ represents a di- to octavalent organic group having 5 to 40 carbon atoms; R⁷ and R⁸ each independently represent a hydroxyl group, a sulfonic acid group, a thiol group or COOR⁹; R⁹ represents a hydrogen atom or a monovalent hydrocarbon group having 1 to 20 carbon atoms; and r and s represent an integer of 0 to 6 and r+s>0.

### Effects of the Invention

According to the present invention, it is possible to obtain organic EL display device which is free from off-pixel and has excellent visibility.

### BRIEF DESCRIPTION OF THE DRAWINGS

FIG. 1 is a cross-sectional view of a TFT substrate having a planarization layer and a pixel division layer.

FIG. 2 is a flow chart showing the production process of an organic EL display device of the present invention.

FIG. 3 is a schematic view of a procedure for fabrication of an organic EL display device in Examples.

### EMBODIMENTS OF THE INVENTION

Embodiments of the present invention will be described in detail

The organic EL display device of the present invention includes at least a substrate, a planarization layer, a first electrode, a pixel division layer, a light emitting pixel and a second electrode. The organic EL display device of the present invention is preferably an active matrix type organic EL display device having a plurality of light emitting pixels formed in a matrix. In the active matrix type display device, it is preferable to use a substrate (hereinafter referred to as “TFT substrate”) in which a thin film transistor (hereinafter referred to as “TFT”) is formed on the substrate. A planarization layer is provided on a TFT substrate so as to cover the lower part of the light emitting pixel and the portion other than the light emitting pixel. Further, a first electrode is provided on the planarization layer so as to cover at least the lower part of the light emitting pixel. A light emitting pixel is provided above the first electrode. Further, a second electrode is provided so as to cover at least the upper part of the light emitting pixel. The plurality of light emitting pixels are divided by an insulating pixel division layer.

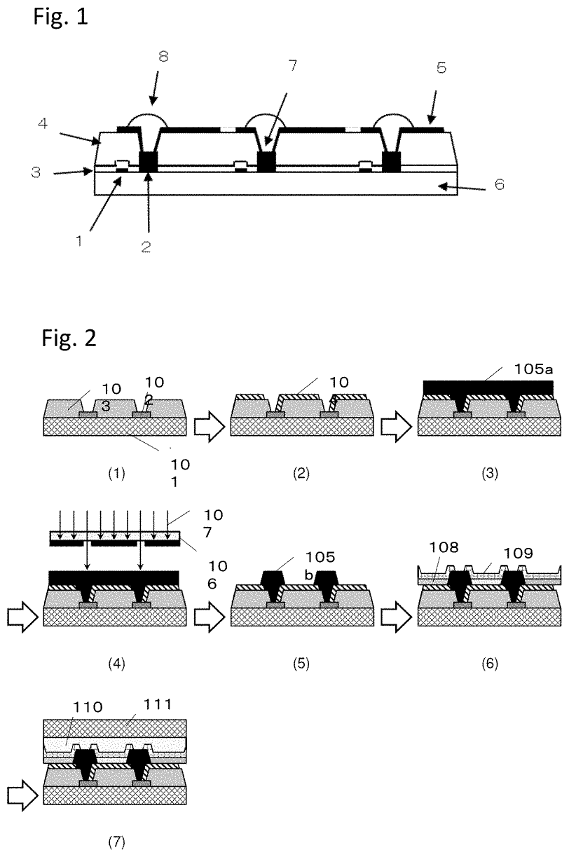

FIG. 1 shows a cross-sectional view of a TFT substrate in a state where a planarization layer and a pixel division layer are formed. A bottom gate type or top gate type TFT 1 is provided in a matrix on the substrate 6, and a TFT insulating layer 3 is formed so as to cover TFT 1. Further, a wire line 2 electrically connected to TFT 1 is provided under TFT insulating layer 3. The TFT insulating layer 3 is provided with a contact hole 7 for opening the wire line 2. A planarization layer 4 is provided above these, and the planarization layer 4 is provided with an opening so as to reach the contact hole 7 on the wire line 2. Then, ITO 5 (transparent electrode) is formed on the planarization layer 4. Here, ITO 5 is the first electrode of the organic EL display device. The ITO 5 is electrically connected to the wire line 2 via the contact hole 7. Then, a pixel division layer 8 is formed so as to cover the peripheral edge of the ITO 5. This organic EL display device may be either a top emission type that emits emitted light from the opposite side of the substrate 6, or a bottom emission type that extracts light from the substrate 6 side.

A color display can be obtained by arranging light emitting pixels having the respective light emitting peak wavelengths in the ranges of red, blue and green. In the color display, the peak wavelength of light in the red range to be displayed is usually in the range of 560 to 700 nm, the peak wavelength of light in the green range is in the range of 500 to 560 nm, and the peak wavelength of light in the blue range is in the range of 420 to 500 nm.

### <Substrate>

It is possible to appropriately select, as the substrate, those which are preferable for supporting a display device or transporting to a post-process, including metal, glass, resin film or the like. In particular, when it is necessary to have the translucency, glass or a resin film is used.

It is possible to use, as the glass substrate, soda lime glass, alkaline-free glass and the like. The thickness of the substrate may be sufficient to maintain the mechanical strength. As for the material of the glass, alkaline-free glass is preferable because it is preferable that the smaller the amount of ions eluted from the glass, the better. It is also possible to use soda lime glass coated with a barrier coat such as SiO₂ which is commercially available.

The resin film having excellent translucency preferably contains a resin material selected from polybenzoxazole, polyamideimide, polyimide, polyamide and poly(p-xylylene). The resin film may contain these resin materials alone or contain a plurality of types thereof. For example, when the resin film is formed of a polyimide resin, it is possible to form by applying a solution containing polyamic acid (including a partially imidized polyamic acid), which is a precursor of polyimide, or a soluble polyimide on a support substrate, followed by firing. Since the organic EL element is said to be sensitive to oxygen and moisture, a gas barrier layer may be provided on the substrate. In particular, when the resin film is used as the substrate, a highly reliable display device can be obtained by laminating an inorganic thin film.

### <Planarization Layer>

Examples of the material of the planarization layer include an acrylic resin, an epoxy resin, a polyamide resin, a siloxane resin, a polyimide resin, a polybenzoxazole resin, and precursors of these resins. From the viewpoint of the reliability of the organic EL display device, the planarization layer preferably contains a polyimide resin having an imide structure. Further, the planarization layer preferably contains a compound having an indene structure. The compound having an indene structure is a compound derived from the reaction product of a naphthoquinonediazide sulfonic acid ester compound. That is, the fact that the planarization layer contains a compound having an indene structure means that the photosensitive resin composition used to form the planarization layer contains a naphthoquinonediazide sulfonic acid ester compound. By pattern-processing a positive photosensitive resin composition containing a naphthoquinonediazide sulfonic acid ester compound as a photosensitive agent, it is possible to obtain an organic EL display device in which the residue is less likely to be generated in the opening and there are fewer darkspots.

When coloring is required from the viewpoint of the light-shielding property and antireflection, it is preferable that the planarization layer contains a colorant. When the planarization layer contains a colorant, it is preferable to contain, as the colorant, zirconium nitride particles in which a crystallite size determined from a half width of a peak derived from a (111) plane in an X-ray diffraction spectrum using a CuKα ray as an X-ray source is 5 nmn or more 20 nm or less. Use of zirconium nitride particles as the colorant has the effect of shielding visible light. Meanwhile, when the planarization layer is formed by photolithography using the photosensitive resin composition, the zirconium nitride particles have high light transmittance in the ultraviolet range which is the exposure wavelength, thus making it possible to achieve higher sensitivity of the photosensitive resin composition. By setting the crystallite size of the zirconium nitride particles at 20 nm or less, the generation of off-pixel due to a short circuit originating from coarse particles can be suppressed to obtain an organic EL display device with fewer display defects. By setting the crystallite size of the zirconium nitride particles at 5 nm or more, it is possible to obtain an organic EL display device which has excellent visible light-shielding property per unit weight and exerts large effect of reducing external light reflection, and also has excellent visibility.

The thickness of the planarization layer containing zirconium nitride particles having a crystallite size of 5 nm or more and 20 nm or less is preferably 1.5 μm or more and 3.0 μm or less. By setting the thickness at 1.5 μm or more, the effect of reducing external light reflection can be improved. Meanwhile, by setting the thickness at 3.0 μm or less, it is possible to obtain an organic EL display device in which the residue is less likely to be generated in the opening when the photosensitive resin composition is pattern-processed and there are fewer display defects.

The planarization layer can be formed by applying a photosensitive resin composition using a wet coating method such as a spin coating method, a slit coating method, a dip coating method, a spray coating method or a printing method, followed by curing.

### <First Electrode>

It is preferable that a first electrode can efficiently inject electron holes into the light emitting pixel. To extract light, the first electrode is preferably transparent or translucent. Examples of the materials constituting the first electrode include conductive metal oxides such as zinc oxide, tin oxide, indium oxide, indium tin oxide (ITO) and indium zinc oxide (IZO); metals such as gold, silver and chromium; inorganic conductive substances such as copper iodide and copper sulfide; conductive polymers such as polythiophene, polypyrrole and polyaniline; carbon nanotubes, graphene and the like. Two or more of these materials may be used, or they may have a laminated structure made of different materials. The form thereof is not particularly limited, and they may have a fine structure such as metal mesh or silver nanowires. Of these, ITO glass and NESA glass are preferable.

The first electrode preferably has low resistance from the viewpoint of power consumption of the organic EL display device. For example, in the case of an ITO substrate, if the electric resistance value is 300Ω/□ or less, it functions as an element electrode, however, a substrate having about 10Ω/□ is currently available, so that it is more preferable to use a substrate having low resistance of 20Ω/□ or less. The thickness of the first electrode can be arbitrarily selected according to the electric resistance value, and is generally about 45 to 300 nm.

### <Second Electrode>

It is preferable that the second electrode can efficiently inject electrons into the light emitting pixel. Examples of the material constituting the second electrode include metals such as platinum, gold, silver, copper, iron, tin, aluminum and indium; and alloys of these metals and low work function metals such as lithium, sodium, potassium, calcium and magnesium. Two or more of these materials may be used, or they may have a laminated structure made of different materials. Of these, those containing aluminum, silver or magnesium as a main component are preferable from the viewpoints of the electric resistance value, ease of film formation, film stability and luminous efficiency and the like. It is more preferable to contain magnesium and silver, which facilitates injection of electrons into the light emitting layer and can further reduce the driving voltage.

Examples of the method for forming the first electrode and the second electrode include resistance heating, electron beam, sputtering, ion plating, coating and the like.

Of the first electrode and the second electrode, the electrode used as a cathode preferably has a protective layer on the electrode. Examples of the material constituting the protective layer include inorganic substances such as silica, titania and silicon nitride; and organic polymer compounds such as polyvinyl alcohol, polyvinyl chloride and hydrocarbon-based polymer compounds. In the case of a top emission structure which extracts light from the cathode side, the material constituting the protective layer preferably has light transmissivity in the visible light range.

### <Light Emitting Pixel>

The light emitting pixel has the function of displaying an organic EL display device by emitting light. The light emitting pixel has at least a light emitting layer mentioned later. If necessary, the light emitting layer may further include an electron hole injection layer, an electron hole transporting layer, an electron injection layer, an electron transporting layer and the like. The organic EL display device of the present invention preferably has a plurality of light emitting pixels, and the plurality of light emitting pixels are divided by an insulating pixel division layer.

### <Light Emitting Layer>

The light emitting layer is a layer in which a light emitting material is excited by recombination energy due to collision of electron holes and electrons to emit light. The light emitting layer may be a single layer or may be composed by laminating a plurality of layers. The light emitting layer is formed of a light emitting material, that is, a host material or a dopant material. The light emitting layer may be composed of only one of the host material and the dopant material, or may be composed of a combination of the host material and the dopant material. When the light emitting layer is composed of a plurality of layers, each light emitting layer may be composed of only one of the host material and the dopant material, or may be composed of a combination of the host material and the dopant material. From the viewpoint of efficiently utilizing electric energy to obtain light emission with high color purity, the light emitting layer is preferably composed of a combination of the host material and the dopant material. The dopant material may be contained entirely or partially in the host material. The content of the dopant material in the light emitting layer is preferably 30 parts by weight or less, and more preferably 20 parts by weight or less, based on 100 parts by weight of the host material, from the viewpoint of suppressing the concentration quenching phenomenon. The light emitting layer can be formed by a method of co-depositing the host material and the dopant material, a method of mixing the host material and the dopant material in advance, followed by deposition or the like.

Examples of the host material constituting the light emitting material include compounds having a fused aryl ring, such as naphthalene, anthracene, phenanthrene, pyrene, chrysene, naphthacene, triphenylene, perylene, fluoranthene, fluorene and indene. Two or more of these materials may be used to form a light emitting material.

It is possible to preferably use, as the host used when the light emitting layer performs triplet emission (phosphorescence emission), metal-chelated oxinoid compounds, dibenzofuran derivatives, dibenzothiophene derivatives, carbazole derivatives, indolocarbazole derivatives, triazine derivatives, triphenylene derivatives and the like. Of these, compounds having an anthracene skeleton or a pyrene skeleton are more preferable because high-efficiency light emission can be easily obtained.

Examples of the dopant material constituting the light emitting material include fused ring derivatives such as anthracene and pyrene; metal complex compounds such as tris(8-quinolinolato)aluminum; bisstyryl derivatives such as bisstyrylanthracene derivatives and distyrylbenzene derivatives; tetraphenylbutadiene derivatives; dibenzofuran derivatives; carbazole derivatives; indolocarbazole derivatives; polyphenylenevinylene derivatives and the like.

The dopant material used when the light emitting layer performs triplet emission (phosphorescence emission) is preferably a metal complex compound containing at least one metal selected from the group consisting of iridium (Ir), ruthenium (Ru), palladium (Pd), platinum (Pt), osmium (Os) and rhenium (Re). The ligand constituting the metal complex compound can be appropriately selected from the required emission color, the performance of the organic EL display device, and the relationship with the host compound. It is preferable to have a nitrogen-containing aromatic heterocycle such as a phenylpyridine skeleton, a phenylquinoline skeleton or a carbene skeleton, and specific examples thereof include a tris(2-phenylpyridyl)iridium complex, a bis(2-phenylpyridyl) (acetylacetonate)iridium complex, a tetraethylporphyrin platinum complex and the like. Two or more of these materials may be used to form a metal complex compound.

### <Pixel Division Layer>

Examples of the material of the pixel division layer include an acrylic resin, an epoxy resin, a polyamide resin, a siloxane resin, a polyimide resin, a polybenzoxazole resin, and precursors of these resins. From the viewpoint of the reliability of the organic EL display device, the pixel division layer preferably contains a polyimide resin having an imide structure. Further, the pixel division layer preferably contains a compound having an indene structure. The compound having an indene structure is a compound derived from the reaction product of the naphthoquinonediazide sulfonic acid ester compound as mentioned above. By pattern-processing a positive photosensitive resin composition containing a naphthoquinonediazide sulfonic acid ester compound as a photosensitive agent, it is possible to obtain an organic EL display device in which the residue is less likely to be generated in the opening and there are fewer darkspots.

When coloring is required from the viewpoint of light-shielding property and antireflection, it is preferable that the pixel division layer contains a colorant. When the pixel division layer contains a colorant, it is preferable to contain, as the colorant, zirconium nitride particles in which a crystallite size determined from a half width of a peak derived from a (111) plane in an X-ray diffraction spectrum using a CuKα ray as an X-ray source is 5 nm or more 20 nm or less. Use of zirconium nitride particles as the colorant has the effect of shielding visible light. Meanwhile, when the pixel division layer is formed by photolithography using the photosensitive resin composition, the zirconium nitride particles have high light transmittance in the ultraviolet range which is the exposure wavelength, thus making it possible to achieve higher sensitivity of the photosensitive resin composition. By setting the crystallite size of the zirconium nitride particles at 20 nm or less, the generation of off-pixel due to a short circuit originating from coarse particles can be suppressed to obtain an organic EL display device with fewer display defects. By setting the crystallite size of the zirconium nitride particles at 5 nm or more, it is possible to obtain an organic EL display device which has excellent visible light-shielding property per unit weight and exerts large effect of reducing external light reflection, and also has excellent visibility.

The thickness of the pixel division layer containing zirconium nitride particles having a crystallite size of 5 nm or more and 20 nm or less is preferably 1.5 μm or more and 3.0 μm or less. By setting the thickness at 1.5 μm or more, the effect of reducing external light reflection can be improved. Meanwhile, by setting the thickness at 3.0 μm or less, it is possible to obtain an organic EL display device in which the residue is less likely to be generated in the opening when the photosensitive resin composition is patter-processed and there are fewer display defects.

The pixel division layer can be formed by applying a photosensitive resin composition using a wet coating method such as a spin coating method, a slit coating method, a dip coating method, a spray coating method or a printing method, followed by curing.

Only one of the planarization layer and the pixel division layer may contain zirconium nitride particles, or both may contain zirconium nitride particles. When the planarization layer and/or the pixel division layer contain/contains zirconium nitride particles, thereby, external light reflection can be reduced while preventing the generation of the colorant-derived residue when forming the planarization layer and/or the pixel division layer, thus obtaining an organic EL display device having excellent visibility.

The OD value of the planarization layer and the pixel division layer is preferably smaller than the OD value of a black matrix of a color filter mentioned later. By making the OD value of the black matrix higher than the OD value of the planarization layer and pixel division layer, it is possible to obtain an organic EL display device which more sufficiently suppress external light reflection and has high visibility.

It is more preferable that the difference between the OD value of the black matrix and the OD value of the layer containing the zirconium nitride particles of the planarization layer and the pixel division layer is 2.0 or more and 3.5 or less.

When the difference between the OD value of the black matrix and the OD value of the planarization layer and/or the pixel division layer is 2.0 or more, the residue derived from the colorant is less likely to be generated when the planarization layer and/or the pixel division layer is/are formed, and it is possible to suppress darkspots in which local non-light emitting sites are generated in some pixels. Since the difference between the OD value of the planarization layer or the pixel division layer and the OD value of the black matrix is 3.5 or less, it is possible to obtain an organic EL display device which sufficiently suppresses external light reflection and has excellent visibility.

### <Method for Producing Organic EL Display Device>

An example of the method for producing an organic EL display device of the present invention will be described with reference to FIG. 2. In FIG. 2, a cured film of a positive photosensitive resin composition is used as a light-shielding pixel division layer. Note that (1) to (7) in FIG. 2 correspond to the following processes (1) to (7), respectively.

(1) A thin film transistor (hereinafter referred to as “TFT”) 102 is formed on a glass substrate 101. A film of a photosensitive material for a planarization layer is formed on the whole surface of TFT 102, pattern-processed by photolithography and then thermally cured to form a planarization layer 103.

(2) A film of an alloy of magnesium and silver is formed on the whole surface of the planarization layer 103 by sputtering and then pattern-processed by photolithography using a photoresist to form a first electrode 104 which is a reflective electrode.

(3) A positive photosensitive resin composition for a pixel division layer is applied on the whole surface of the first electrode 104 and then prebaked to form a prebaked film 105a.

(4) The prebaked film 105a is irradiated with active actinic rays 107 through a mask 106 having a desired pattern.

(5) The prebaked film 105a was pattern-processed by development, and after optionally performing bleaching exposure and middle baking, the film was thermally cured to form a pixel division layer 105b having a desired pattern.

(6) A film of an EL light emitting material is formed between the pixel division layers 105b by deposition through a mask to form a light emitting pixel 108. A film of ITO is formed on the whole surface of the light emitting pixel 108 by sputtering and then pattern-processed by etching using a photoresist to form a second electrode 109 which is a transparent electrode.

(7) A film of a photosensitive material for a planarization layer is formed on the whole surface of the second electrode 109, pattern-processed by photolithography and then thermally cured to form a cured film 110 for flattening. Further, a cover glass or a color filter 111 is bonded thereon to obtain an organic EL display device.

Examples of the method for pattern-processing a first electrode or a second electrode include etching. Hereinafter, a description will be made using a method for pattern-processing a first electrode by etching as an example.

After forming the first electrode on the substrate, a photoresist is applied on the first electrode and prebaked. Then, by exposing the photoresist through a mask having a desired pattern and developing the exposed photoresist, a photoresist pattern is formed on the first electrode by photolithography. After development, it is preferable to subject the pattern obtained pattern to a heat treatment. Since the photoresist is thermally cured by the heat treatment, leading to an improvement in chemical resistance and dry etching resistance, the photoresist pattern can be preferably used as an etching mask. Examples of a heat treatment device include an oven, a hot plate, infrared rays, a flash annealing device, a laser annealing device and the like. The heat treatment temperature is preferably 70 to 200° C., and the heat treatment time is preferably 30 seconds to several hours.

Subsequently, the first electrode is pattern-processed by etching using the photoresist pattern as the etching mask. Examples of the etching method include wet etching using an etching solution and dry etching using an etching gas. Examples of the etching solution include an acidic or alkaline etching solution, an organic solvent and the like. Two or more thereof may be used as the etching solution.

After etching, a pattern of the first electrode is obtained by removing the photoresist remaining on the first electrode.

The light emitting pixel can be formed by, for example, a mask vapor deposition method or an inkjet method. Examples of a typical mask vapor deposition method include a method in which a vapor deposition mask having a desired pattern as an opening is arranged on the vapor deposition source side of the substrate and vapor deposition is performed.

### <Color Filter>

The organic EL display device can further include a color filter having a black matrix in order to enhance the effect of reducing external light reflection.

The black matrix preferably contains, for example, resins such as epoxy-based resins, acrylic resins, urethane-based resins, polyester-based resins, polyimide resins, polyolefin-based resins or siloxane resins.

The black matrix contains a colorant. Examples of the colorant include black organic pigments, mixed color organic pigments, inorganic pigments and the like. Examples of the black organic pigment include carbon black, perylene black, aniline black, and benzofuranone-based pigments. Examples of the mixed color organic pigment include those obtained by mixing two or more of pigments such as red, blue, green, violet, yellow, magenta and/or cyan to produce a pseudo-black color. Examples of the black inorganic pigment include graphite; fine particles of metals such as titanium, copper, iron, manganese, cobalt, chromium, nickel, zinc, calcium and silver; metal oxides; metal composite oxides; metal sulfides; metal nitrides; metal oxynitrides; metal carbides and the like. Of these, preferred are carbon black, titanium nitride and titanium carbide each having high light-shielding property, and composite particles of these colorants and metals such as silver.

The OD value of the black matrix is preferably 1.5 or more, more preferably 2.5 or more, and still more preferably 4.5 or more.

The method for forming a black matrix is generally photolithography using a photosensitive resin composition or non-photosensitive resin composition containing a colorant. When using the non-photosensitive resin composition containing a colorant, a photoresist film is further formed on the coating film of the composition, followed by exposure and further development for patterning to obtain a black matrix having a desired pattern. The black matrix thus obtained is heat-treated by a hot air oven or hot plate at 180 to 300° C. for 5 to 60 minutes.

The color filter can have colored pixels in the opening of the black matrix.

Examples of the colorant contained in the resin composition for forming the colored pixels include organic pigments, inorganic pigments or dyes. Organic pigments or dyes are preferable since the transparency of the colored pixels is enhanced. Examples of the red pigment include Pigment Red (hereinafter referred to as “PR”) 9, PR48, PR97, PR122, PR123, PR144, PR149, PR166, PR168, PR177, PR179, PR180, PR192, PR209, PR215, PR216, PR217, PR220, PR223, PR224, PR226, PR227, PR228, PR240, PR254, or diketopyrrolopyrrole pigments having a bromine group. Examples of the orange pigment include Pigment Orange (hereinafter referred to as “PO”) 13, P031, P036, P038, P040, P042, P043, P051, P055, P059, P061, P064, P065 or P071. Examples of the greed pigment include Pigment Green (hereinafter referred to as “PG”) 7, PG10, PG36 or PG58. Examples of the yellow pigment include Pigment Yellow (hereinafter referred to as “PY”) 12, PY13, PY17, PY20, PY24, PY83, PY86, PY93, PY95, PY109, PY110, PY117, PY125, PY129, PY137, PY138, PY139, PY147, PY148, PY150, PY153, PY154, PY166, PY168 or PY85. Examples of the blue pigment include Pigment Blue (hereinafter referred to as “PB”) 15:3, PB15:4, PB15:6, PB21, PB22, PB60 or PB64. Examples of the violet pigment include Pigment Violet (hereinafter referred to as “PV”) 19, PV23, PV29, PV30, PV37, PV40 or PV50 (all of the above numbers are Color Index Nos.).

The method for forming colored pixels is generally photolithography which is the same as in the black matrix.

Examples of the step of laminating the color filter substrate with the organic EL element substrate include a method in which the color filter substrate and the organic EL element substrate are opposed to each other in a vacuum, a reduced pressure atmosphere, a nitrogen atmosphere or the like and a sealant is applied, and then the sealant is cured by light or heating.

### <Photosensitive Resin Composition>

Subsequently, a description will be made of a photosensitive resin composition which is a raw material of a cured film constituting a planarization layer and/or a pixel division layer which contain(s) zirconium nitride particles (A). The photosensitive resin composition includes zirconium nitride particles (A), an alkaline soluble resin (B) including a repeating structural unit represented by general formula (1) and/or a repeating structural unit represented by general formula (2), an organic solvent (C) and photoacid generator (D), and an acid equivalent of the alkaline soluble resin (B) is 200 g/mol or more and 500 g/mol or less:

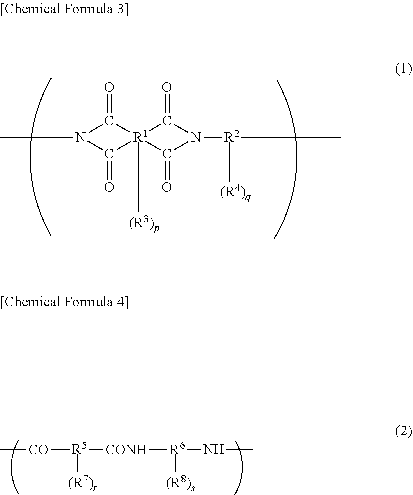

wherein, in general formula (1), R¹ represents a tetra- to decavalent organic group having 5 to 40 carbon atoms, R² represents a di- to octavalent organic group having 5 to 40 carbon atoms; R³ and R⁴ each independently represent a hydroxyl group, a carboxy group, a sulfonic acid group or a thiol group; and p and q represent an integer of 0 to 6 and p+q>0; and
wherein, in general formula (2), R⁵ represents a di- to octavalent organic group having 5 to 40 carbon atoms, R⁶ represents a di- to octavalent organic group having 5 to 40 carbon atoms; R⁷ and R⁸ each independently represent a hydroxyl group, a sulfonic acid group, a thiol group or COOR⁹; R⁹ represents a hydrogen atom or a monovalent hydrocarbon group having 1 to 20 carbon atoms; and r and s represent an integer of 0 to 6 and r+s>0.

As the zirconium nitride particles (A) (hereinafter sometimes referred to as component (A)), those having low contents of zirconium oxide and zirconium oxynitride, which are by-products of zirconium nitride, are preferable. As for the contents of zirconium oxide and zirconium nitride in the component (A), a ratio of an X-ray diffraction peak intensities of zirconium oxide and zirconium nitride to an X-ray diffraction peak intensity of zirconium nitride is preferably 1.0 or less, respectively, more preferably 0.5 or less, and still more preferably so small that the X-ray diffraction peaks of zirconium oxide and zirconium nitride are not observed.

The component (A) more preferably contains particles of a composite nitride of a zirconium atom and a metal atom other than the zirconium atom. By combining zirconium nitride with the metal atom other than the zirconium atom, it is possible to suppress the oxidation of zirconium nitride and to improve the visible light-shielding property and to improve the stability as an inorganic pigment.

Here, the metal atom is an atom of elements selected from Groups 1 to 12 of the Periodic Table excluding hydrogen atoms, and zinc, cadmium, mercury, copernicium, aluminum, gallium, indium, thallium, tin, lead, bismuth and polonium.

Examples of the metal atom other than the zirconium atom are not particularly limited, and preferred examples thereof include atoms of at least one selected from titanium, aluminum, copper, silver, gold, platinum, palladium, nickel, tin, cobalt, rhodium, iridium, iron, ruthenium, osmium, manganese, molybdenum, tungsten, niobium, tantalum, calcium, bismuth, antimony, lead, and alloys thereof. Examples of more preferable metal atom include a titanium or an aluminum atom.

The content of the metal atom other than the zirconium atom in the component (A) is preferably 2% by mass or more and 20% by mass or less, and more preferably 3% by mass or more and 15% by mass or less, based on the total mass of the component (A). By setting the content of the metal atom other than the zirconium atom at 2% by mass or more, the visible light-shielding property can be further improved. Meanwhile, by setting the content at 20% by mass or less, the sensitivity can be further improved.

Here, the content of the zirconium atom and the content of the metal atom in the component (A) can be analyzed by ICP atomic emission spectroscopy. The content of the nitrogen atom can be analyzed by inert gas fusion thermal conductivity detection. The content of the oxygen atom can be analyzed by inert gas fusion infrared absorption spectrometry.

The component (A) preferably has a specific surface area of 5 m²/g or more and 100 m²/g or less. By setting the specific surface area of the zirconia compound particle at 5 m²/g or more, the pigment can be easily finely dispersed, and the dispersion stability in the photosensitive resin composition and the flatness and the adhesion of the photosensitive resin film can be improved. Meanwhile, by setting the specific surface area at 100 m²/g or less, the reaggregation of the pigment can be suppressed, and the dispersion stability in the photosensitive resin composition and the light-shielding property of the photosensitive resin film can be further improved. The specific surface area is more preferably 60 m²/g or less. Here, the specific surface area of the component (A) can be determined by a BET multipoint method based on a nitrogen gas adsorption method using a gas adsorption specific surface area measuring device. Examples of the means for setting the specific surface area within the above-mentioned range include a method of adjusting crystal growth conditions during particle synthesis by a gas phase reaction. For example, in a thermal plasma method, the specific surface area can be easily adjusted to the above-mentioned range by adjusting the cooling time and the cooling speed after vaporizing the particle.

As a method for producing a component (A), a gas phase reaction method such as an electric furnace method or a thermal plasma method is generally used. Of these methods, the thermal plasma method is preferable since less impurities are mixed, the zirconia nitride particle easily has a uniform particle size, and the productivity is high. Examples of the method for generating thermal plasma include direct current arc discharge, multilayer arc discharge, radio frequency (RF) plasma, and hybrid plasma. Of these methods, the radio frequency plasma is preferable because less impurities from the electrode are mixed. Specific examples of the method include a method in which zirconium is vapored and atomized in a nitrogen atmosphere by a thermal plasma method to synthesize zirconium nitride particles when zirconium nitride particles are produced (for example, Journal of the Surface Science Society of Japan, Vol. 5(1984), No. 4), a method in which a gas phase reaction of zirconium chloride with ammonia is caused by an electric furnace method to synthesize zirconium nitride particles (for example, Journal of the Surface Science Society of Japan, Vol. 8(1987), No. 5), and a method in which a mixture of zirconium dioxide, magnesium oxide, and a magnesium metal is fired at high temperature in a nitrogen atmosphere to obtain lower zirconium oxide-zirconium nitride composite (for example, JP 2009-91205 A).

The photosensitive resin composition of the present invention may contain other colorants, if necessary.

Examples of the organic black pigment include carbon black, perylene black, aniline black, or benzofuranone-based pigments (mentioned in JP 2012-515233 W).

Examples of the blue pigment include C.I. Pigment Blue 15, 15:1, 15:2, 15:3, 15:4, 15:6 or 60.

Examples of the green pigment include C.I. Pigment Green 7, 36 or 58.

Examples of the yellow pigment include C.I. Pigment Yellow 83, 117, 129, 138, 139, 150, 154, 155, 18 or 185.

Examples of the violet pigment include C.I. Pigment Violet 19 or 23.

Examples of the red pigment include C.I. Pigment Red 48: 1122, 168, 177, 202, 206, 207, 209, 224, 242 or 254.

Examples of the orange pigment include C.I. Pigment Orange 38 or 71.

By combining these pigments, a photosensitive resin composition having desired optical properties can be obtained.

The photosensitive resin composition of the present invention is an alkaline soluble resin (B) including a repeating structural unit represented by general formula (1) and/or a repeating structural unit represented by general formula (2) (hereinafter sometimes referred to as component (B)).

The alkaline soluble resin in the present invention refers to a resin having any alkaline soluble group selected from a hydroxyl group, a carboxy group, a sulfonic acid group and a thiol group.

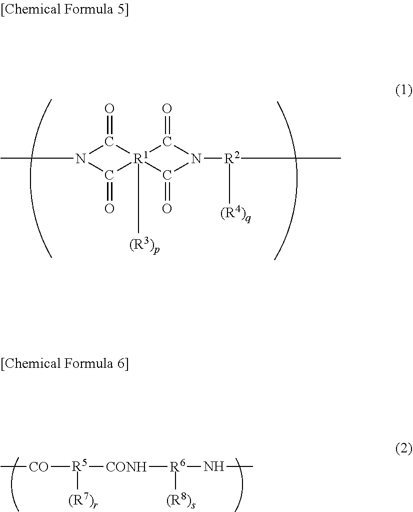

In general formula (1), R¹ represents a tetra- to decavalent organic group having 5 to 40 carbon atoms, R² represents a di- to octavalent organic group having 5 to 40 carbon atoms, R³ and R⁴ each independently represent a hydroxyl group, a carboxy group, a sulfonic acid group or a thiol group, p and q represent an integer of 0 to 6 and p+q>0.

In general formula (2), R⁵ represents a di- to octavalent organic group having 5 to 40 carbon atoms, R⁶ represents a di- to octavalent organic group having 5 to 40 carbon atoms, R⁷ and R⁸ each independently represent a hydroxyl group, a sulfonic acid group, a thiol group or COOR⁹, R⁹ represents a hydrogen atom or a monovalent hydrocarbon group having 1 to 20 carbon atoms, and r and s represent an integer of 0 to 6 and r+s>0.

The component (B) preferably 5 to 100,000 repeating structural units in total selected from repeating structural units of general formula (1) and general formula (2) in one molecule. Further, the component (B) may have, in addition to the structural units represented by general formula (1) and/or general formula (2), other structural units. In this case, the component (B) preferably has the structural unit selected from structural units of general formula (1) and general formula (2) in the amount of 50 mol % or more based on all the structural units.

In general formula (1), R¹−(R³)ₚ represents an acid dianhydride residue. R¹ is a tetra- to decavalent organic group having 5 to 40 carbon atoms, and preferably an organic group having an aromatic ring or a cyclic aliphatic group.

Specific examples of the acid dianhydride include aromatic tetracarboxylic dianhydrides such as pyromellitic dianhydride, 3,3′,4,4′-biphenyltetracarboxylic dianhydride, 2,3,3′,4′-biphenyltetracarboxylic dianhydride, 2,2′,3,3′-biphenyltetracarboxylic dianhydride, 3,3′,4,4′-benzophenonetetracarboxylic dianhydride, 2,2′,3,3′-benzophenonetetracarboxylic dianhydride, 2,2-bis(3,4-dicarboxyphenyl)propane dianhydride, 2,2-bis(2,3-dicarboxyphenyl)propane dianhydride, 1,1-bis(3,4-dicarboxyphenyl)ethane dianhydride, 1,1-bis(2,3-dicarboxyphenyl)ethane dianhydride, bis(3,4-dicarboxyphenyl)methane dianhydride, bis(2,3-dicarboxyphenyl)methane dianhydride, bis(3,4-dicarboxyphenyl)ether dianhydride, 1,2,5,6-naphthalenetetracarboxylic dianhydride, 9,9-bis(3,4-dicarboxyphenyl)fluorenic dianhydride, 9,9-bis{4-(3,4-dicarboxyphenoxy)phenyl}fluorenic dianhydride, 2,3,6,7-naphthalenetetracarboxylic dianhydride, 2,3,5,6-pyridinetetracarboxylic dianhydride, 3,4,9,10-perylenetetracarboxylic dianhydride, 2,2-bis(3,4-dicarboxyphenyl)hexafluoropropane dianhydride, and acid dianhydrides having the structure shown below; and aliphatic tetracarboxylic dianhydrides such as butanetetracarboxylic dianhydride and 1,2,3,4-cyclopentanetetracarboxylic dianhydride. Two or more of these acid dianhydrides may be used.

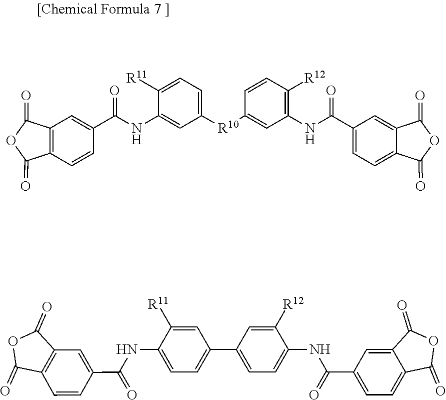

R¹⁰ represents an oxygen atom, C(CF₃)₂ or C(CH₃)₂. R¹¹ and R¹² represent a hydrogen atom or a hydroxyl group.

In general formula (2), R⁵−(R⁷)ᵣ represents a carboxylic acid residue. R⁵ is a di- to octavalent organic group having 5 to 40 carbon atoms, and preferably an organic group having an aromatic ring or a cyclic aliphatic group.

Examples of the acid are as follows. Examples of the dicarboxylic acid include terephthalic acid, isophthalic acid, diphenyletherdicarboxylic acid, bis(carboxyphenyl)hexafluoropropane, biphenyldicarboxylic acid, benzophenonedicarboxylic acid and triphenyldicarboxylic acid; examples of the tricarboxylic acid include trimellitic acid, trimesic acid, diphenylethertricarboxylic acid and biphenyltricarboxylic acid; examples of the tetracarboxylic acid include pyromellitic acid, 3,3′,4,4′-biphenyltetracarboxylic acid, 2,3,3′,4′-biphenyltetracarboxylic acid, 2,2′,3,3′-biphenyltetracarboxylic acid, 3,3′,4,4′-benzophenonetetracarboxylic acid, 2,2′,3,3′-benzophenonetetracarboxylic acid, 2,2-bis(3,4-dicarboxyphenyl)hexafluoropropane, 2,2-bis(2,3-dicarboxyphenyl)hexafluoropropane, 1,1-bis(3,4-dicarboxyphenyl)ethane, 1,1-bis(2,3-dicarboxyphenyl)ethane, bis(3,4-dicarboxyphenyl)methane, bis(2,3-dicarboxyphenyl)methane, bis(3,4-dicarboxyphenyl)ether, 1,2,5,6-naphthalenetetracarboxylic acid, 2,3,6,7-naphthalenetetracarboxylic acid, 2,3,5,6-pyridinetetracarboxylic acid, 3,4,9,10-perylenetetracarboxylic acid, aromatic tetracarboxylic acid having the structure shown below; and aliphatic tetracarboxylic acids such as butanetetracarboxylic acid and 1,2,3,4-cyclopentanetetracarboxylic acid. Two or more of these acid dianhydrides may be used.

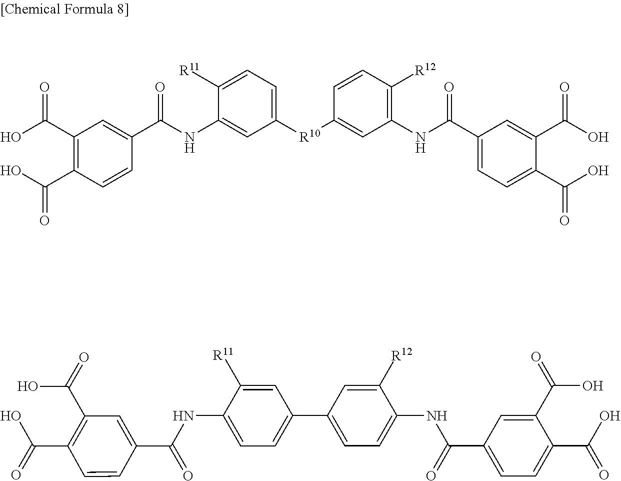

R¹⁰ represents an oxygen atom, C(CF₃)₂ or C(CH₃)₂. R¹¹ and R¹² each independently represent a hydrogen atom or a hydroxyl group.

In the residue of tricarboxylic acids and the residue of tetracarboxylic acids of these acids, one or two carboxyl groups correspond to the R⁷ group in general formula (2). More preferred are those in which one to four hydrogen atoms of the dicarboxylic acids, tricarboxylic acids and tetracarboxylic acids exemplified above are substituted with the R⁷ group in general formula (2), and preferably with a hydroxyl group. These acids can be used as they are, as acid anhydrides or active esters.

R²−(R⁴)_{q} in general formula (1) and R⁶−(R⁸)ₛ in general formula (2) represent a diamine residue. R² and R⁶ are a di- to octavalent organic group having 5 to 40 carbon atoms, and preferably an organic group having an aromatic ring or a cyclic aliphatic group.

Specific examples of the diamine include 3,4′-diaminodiphenyl ether, 4,4′-diaminodiphenyl ether, 3,4′-diaminodiphenylmethane, 4,4′-diaminodiphenylmethane, 1,4-bis(4-aminophenoxy)benzene, benzidine, m-phenylenediamine, p-phenylenediamine, 1,5-naphthalenediamine, 2,6-naphthalenediamine, bis(4-aminophenoxy)biphenyl, bis{4-(4-aminophenoxy)phenyl}ether, 1,4-bis(4-aminophenoxy)benzene, 2,2′-dimethyl-4,4′-diaminobiphenyl, 2,2′-diethyl-4,4′-diaminobiphenyl, 3,3′-dimethyl-4,4′-diaminobiphenyl, 3,3′-diethyl-4,4′-diaminobiphenyl, 2,2′,3,3′-tetramethyl-4,4′-diaminobiphenyl, 3,3′,4,4′-tetramethyl-4,4′-diaminobiphenyl, 2,2′-di(trifluoromethyl)-4,4′-diaminobiphenyl, 9,9-bis(4-aminophenyl)fluorene, compounds in which at least some of the hydrogen atoms in these aromatic rings are substituted with an alkyl group or a halogen atom, aliphatic cyclohexyldiamine, methylenebiscyclohexylamine, and diamines having the structure shown below. Two or more of these acid dianhydrides may be used.

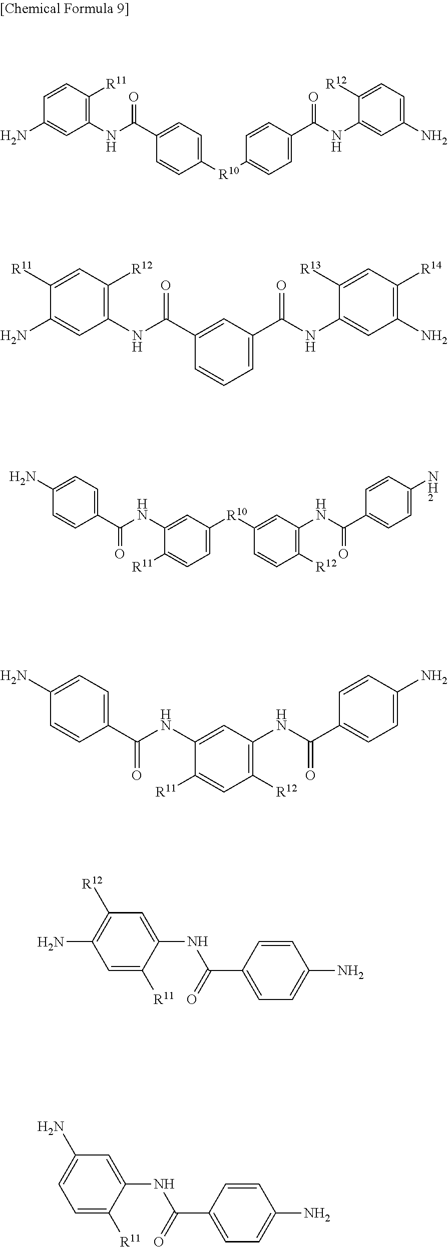

R¹⁰ represents an oxygen atom, C(CF₃)₂ or C(CH₃)₂. R¹¹ to R¹⁴ each independently represent a hydrogen atom or a hydroxyl group.

These diamines can be used as diamines, as corresponding diisocyanate compounds or corresponding trimethylsilylated diamines.

By blocking the terminal of these resins with a monoamine having an acidic group, an acid anhydride, an acid chloride or a monocarboxylic acid, a resin having an acidic group at the main chain terminal can be obtained.

Preferred examples of the monoamine include 2-aminobenzoic acid, 3-aminobenzoic acid, 4-aminobenzoic acid, 4-aminosalicylic acid, 5-aminosalicylic acid, 6-aminosalicylic acid, 2-aminophenol, 3-aminophenol, 4-aminophenol and the like. Two or more of these acid dianhydrides may be used.

Preferred examples of the acid anhydride, acid chloride and monocarboxylic acid include acid anhydrides such as phthalic anhydride, maleic anhydride and nadic anhydride; monocarboxylic acids such as 3-carboxyphenol, 4-carboxyphenol, 3-carboxythiophenol, and 4-carboxythiophenol, and monoacid chloride compounds in which carboxy groups of these monocarboxylic acids are acid-chloridized; and monoacid chloride compounds in which only one carboxy group of dicarboxylic acids such as terephthalic acid, phthalic acid, maleic acid and cyclohexanedicarboxylic acid is acid-chloridized. Two or more of these acid dianhydrides may be used.

The content of the terminal blocking agents such as monoamines, acid anhydrides, acid chlorides and monocarboxylic acids mentioned above is preferably 2 to 25 mol % based on 100 mol % of the total acid and amine components constituting the resin.

The acid equivalent of the component (B) is 200 g/mol or more and 500 g/mol or less.

When the acid equivalent of the component (B) is less than 200 g/mol, for example, when a cured film of a positive photosensitive resin composition is obtained, the alkaline solubility of the unexposed area increases, and the difference in dissolution rate between the unexposed area and the exposed are is too small to form a desired pattern. By setting the acid equivalent at 200 g/mol or more, and more preferably 300 g/mol or more, the solubility of the unexposed area can be suppressed, thus enabling formation of a pattern with less residue in the opening due to adhesion of an eluate from the unexposed area.

By setting the acid equivalent at 500 g/mol or less, it is possible to obtain a photosensitive resin composition which has an acidic group sufficient to promote dispersion stabilization of the component (A), and has excellent storage stability without using a polymer dispersant. In order to sufficiently secure the dispersion stability of the component (A), the acid equivalent is more preferably 450 g/mol or less. The acid equivalent as used herein means the mass of the resin per 1 mol of the acidic group, and the unit is g/mol. The number of acidic groups in the resin can be determined from the acid equivalent value, and the acid equivalent value can also be calculated from the acid value.

Examples of the acidic group contained in the component (B) include a carboxy group, a hydroxyl group, a sulfonic acid group and a thiol group. When the photosensitive resin composition of the present invention is pattern-processed on a metal substrate, the acidic group contained in the component (B) is preferably an acidic group having low polarity from the viewpoint of suppressing the residue on the metal substrate, and specifically, a carboxy group or a hydroxyl group is preferable. It is more preferable that the component (B) contains a carboxy group from the viewpoint that the pigment dispersion can be further stabilized by higher acidity.

The component (B) of the present invention is synthesized by a known method. When the component (B) is a polyamic acid or a polyamic acid ester, examples of the production method include a method in which a tetracarboxylic dianhydride is reacted with a diamine compound at a low temperature, a method in which a diester is obtained by a tetracarboxylic dianhydride and an alcohol, and then the diester is reacted with an amine in the presence of a condensing agent, a method in which a diester is obtained by a tetracarboxylic dianhydride and an alcohol, and the remaining dicarboxylic acid is acid-chloridized, followed by a reaction with an amine and the like.

In the case of a polyhydroxyamide as the component (B), it can be produced by a production method of condensation-reacting a bisaminophenol compound with a dicarboxylic acid. Specific examples thereof include a method in which a dehydrating condensing agent such as dicyclohexylcarbodiimide (DCC) is reacted with an acid, and a bisaminophenol compound is added thereto, a method in which a solution of a dicarboxylic acid dichloride is added dropwise in a solution of a bisaminophenol compound prepared by adding a tertiary amine such as pyridine and the like.

In the case of a polyimide as the component (B), it can be produced by dehydration and ring-closing of the polyamic acid or the polyamic acid ester produced by the above-mentioned method through heating or a chemical treatment with acid, base or the like.

The photosensitive resin composition of the present invention contains an organic solvent (C) (hereinafter sometimes referred to as component (C)). Examples of the component (C) include ethers, acetates, esters, cyclic esters, ketones, aromatic hydrocarbons, amides, alcohols and the like.

Examples of the esters include ethylene glycol monomethyl ether, ethylene glycol monoethyl ether, diethylene glycol monomethyl ether, diethylene glycol monoethyl ether, propylene glycol monomethyl ether (hereinafter referred to as “PGME”), propylene glycol monoethyl ether, dipropylene glycol monomethyl ether, dipropylene glycol monoethyl ether, dipropylene glycol dimethyl ether, tetrahydrofuran and the like.

Examples of the acetates include butyl acetate, ethylene glycol monomethyl ether acetate, ethylene glycol monoethyl ether acetate, propylene glycol monomethyl ether acetate, 3-methoxybutyl acetate, ethylene glycol monobutyl ether acetate, diethylene glycol monomethyl ether acetate, diethylene glycol monoethyl ether acetate, propylene glycol monomethyl ether acetate, propylene glycol monoethyl ether acetate, dipropylene glycol methyl ether acetate, 3-methoxy-3-methyl-1-butyl acetate, 1,4-butanediol diacetate, 1,3-butylene glycol diacetate, 1,6-hexanediol diacetate and the like.

Examples of the esters include lactic acid alkyl esters such as methyl 2-hydroxypropionate (hereinafter referred to as methyl lactate) and ethyl 2-hydroxypropionate; ethyl 2-hydroxy-2-methylpropionate, methyl 3-methoxypropionate, ethyl 3-methylpropionate, methyl 3-ethoxypropionate, ethyl 3-ethoxypropionate, ethyl ethoxyacetate, ethyl hydroxyacetate, methyl 2-hydroxy-3-methylbutanoate, 3-methoxybutyl acetate, 3-methyl-3-methoxybutyl acetate, 3-methyl-3-methoxybutyl propionate, ethyl acetate, n-propyl acetate, n-butyl propionate, ethyl butyrate and the like.

Examples of the cyclic esters include β-propiolactone, γ-butyrolactone, γ-valerolactone, δ-valerolactone, γ-caprolactone or ε-caprolactone.

Examples of the ketones include methyl ethyl ketone, cyclohexanone, 2-heptanone, 3-heptanone and the like.

Examples of aromatic hydrocarbons include toluene, xylene and the like. Examples of the amides include N-methylpyrrolidone, N,N-dimethylformamide, N,N-dimethylacetamide and the like.

Examples of alcohols include butyl alcohol, isobutyl alcohol, pentanol, 4-methyl-2-pentanol, 3-methyl-2-butanol, 3-methyl-3-methoxybutanol, diacetone alcohol and the like. Two or more of these alcohols may be contained.

Particularly, it is preferable that the organic solvent (C) contains a cyclic ester solvent (C-1) having a boiling point of 150° C. or higher under atmospheric pressure (hereinafter sometimes referred to as component (C-1)) and an organic solvent (C-2) having a boiling point of lower than 150° C. (hereinafter sometimes referred to as component (C-2)), and that the content of the component (C-1) in 100% by mass of the component (C) is 10% by mass or more and 40% by mass or less.

By containing the component (C-1) and the component (C-2) and setting the content of the component (C-1) in 100% by mass of the component (C) at 10% by mass or more and 40% by mass or less, the dispersion stability of the component (A) in the component (B) can be improved.

Specific examples of the component (C-1) include γ-butyrolactone, γ-valerolactone, δ-valerolactone, γ-caprolactone or ε-caprolactone. From the viewpoint of the solubility of the component (B), it is preferable to contain γ-butyrolactone, and it is more preferable that the component (C-1) is composed only of γ-butyrolactone.

By containing the component (C-2), suitable volatility and drying property during coating by a die coater can be realized. Examples of the component (C-2) include ethylene glycol monomethyl ether, ethylene glycol monoethyl ether, propylene glycol monomethyl ether, propylene glycol monoethyl ether, propyl acetate, butyl acetate, isobutyl acetate, acetyl acetone, methyl propyl ketone, methyl butyl ketone, methyl isobutyl ketone, cyclopentanone, butyl alcohol, isobutyl alcohol, pentanol, 4-methyl-2-pentanol, methyl lactate, toluene, xylene and the like. From the viewpoint of reducing the solubility of the alkaline soluble resin and the residual amount of the solvent during drying when preparing a photosensitive resin composition, reducing the developed film loss in the unexposed area, and suppressing the residue in the opening due to adhesion of an eluate from the unexposed area, it is preferable that the component (C-2) contains propylene glycol monomethyl ether and/or methyl lactate, and it is more preferable that the component (C-2) is composed only of propylene glycol monomethyl ether and/or methyl lactate.

The photosensitive resin composition of the present invention may contain, in addition to the component (C-1) and the component (C-2), any organic solvent.

When the mass of the component (C-1) is W_{c1} and the mass of the component (C-2) is W_{c2}, the mass ratio W_{c2}/W_{c1} of the component (C-1) and the component (C-2) in the component (C) is preferably 9.0 or less from the viewpoint of enhancing the dispersion stability of the component (A). Further, by setting Wc₂/W_{c1} at 1.5 or more, suitable volatility and drying property during coating can be realized, and for example, when a positive photosensitive resin composition is prepared, it becomes easy to obtain a cured film with less developed film loss in the unexposed area and excellent patterning properties.

The photosensitive resin composition of the present invention contains a photoacid generator (D). Since the photoacid generator generates an acid in the light-irradiated area to increase the solubility of the light-irradiated area in the aqueous alkaline solution, it is possible to obtain a positive photosensitive resin composition in which the light-irradiated area is dissolved.

Examples of the photoacid generator (D) include quinonediazide compounds, sulfonium salts, phosphonium salts, diazonium salts, iodonium salts and the like. Of the photoacid generators (D), the quinonediazide compound is particularly preferable in that a pattern with high sensitivity and high resolution can be obtained without undergoing a heat treatment after exposure.

The quinonediazide compound is preferably a compound in which a sulfonic acid of naphthoquinonediazide is bonded to a compound having a phenolic hydroxyl group by an ester. It is possible to exemplify, as the preferred compound having a phenolic hydroxyl group used herein, those obtained by introducing 4-naphthoquinonediazidesulfonic acid or 5-naphthoquinonediazidesulfonic acid into compounds such as Bis-Z, BisP-EZ, TekP-4HBPA, TrisP-HAP, TrisP-PA, TrisP-SA, TrisOCR-PA, BisOCHP-Z, BisP-MZ, BisP-PZ, BisP-IPZ, BisOCP-IPZ, BisP-CP, BisRS-2P, BisRS-3P and BisP-OCHP (trade names, manufactured by Honshu Chemical Industry Co., Ltd.), BIR-OC, BIP-PC, BIR-PC, BIR-PTBP, BIR-PCHP, BIP-BIOC-F, 4PC, BIR-BIPC-F and TEP-BIP-A (trade names, manufactured by ASAHI YUKIZAI CORPORATION), and 2,6-dimethoxymethyl-4-tert-butylphenol, 2,6-dimethoxymethyl-p-cresol, bisphenol A, bisphenol E, methylenebisphenol and BisP-AP (trade names, manufactured by Honshu Chemical Industry Co., Ltd.) by an ester bond, and other compounds can also be used.

The 4-naphthoquinonediazidosulfonyl ester compound has absorption in the i-ray range of a mercury lamp and is suitable for i-ray exposure. The 5-naphthoquinonediazidosulfonyl ester compound has absorption in the extended g-ray range of a mercury lamp and is suitable for g-ray exposure.

Therefore, it is preferable to select a 4-naphthoquinonediazidesulfonyl ester compound or a 5-naphthoquinonediazidosulfonyl ester compound depending on the wavelength to be exposed. The photoacid generator (D) can also contain a naphthoquinonediazidesulfonyl ester compound having both a 4-naphthoquinonediazidosulfonyl group and a 5-naphthoquinonediazidosulfonyl group in the same molecule, or can contain a mixture of 4-naphthoquinonediazide ester compound and a 5-naphthoquinonediazidesulfonyl ester compound.

The naphthoquinonediazide compound can be synthesized by an esterification reaction between a compound having a phenolic hydroxyl group and a quinonediazidesulfonic acid compound, and can be synthesized by a known method. By using these naphthoquinonediazide compounds, the resolution, sensitivity and residual film ratio are further improved.

The content of the photoacid generator (D) is preferably 0.1 part by mass or more and 30 parts by mass or less based on 100 parts by mass of the component (B). By setting the content of the photoacid generator (D) at 0.1 part by mass or more, it becomes easy to form a pattern of the photosensitive resin composition. By setting the content of the photoacid generator (D) at 30 parts by mass or less, the amount of outgas derived from the photoacid generator can be suppressed.

The photosensitive resin composition of the present invention may further contain a thermal crosslinking agent. The thermal crosslinking agent refers to a compound having at least two thermally reactive functional groups such as an alkoxymethyl group, a methylol group, an epoxy group and an oxetanyl group in the molecule. The thermal crosslinking agent enables crosslinking of the alkali-soluble resin (B) or other additive components to enhance the heat resistance, chemical resistance and hardness of the film after thermal curing.

Preferred examples of compounds having at least two alkoxymethyl or methylol groups include TriML-P, TriML-35XL, TML-HQ, TML-BP, TML-pp-BPF, TML-BPE, TML-BPA, TML-BPAF, TML-BPAP, TMOM-BP, TMOM-BPE, TMOM-BPA, TMOM-BPAF, TMOM-BPAP, HML-TPPHBA, HML-TPHAP, HMOM-TPPHBA and HMOM-TPHAP (all of which are trade names, manufactured by Honshu Chemical Industry Co., Ltd.), and NIKALAC (registered trademark) MX-290, NIKALAC MX-280, NIKALAC MX-270, NIKALAC MX-279, NIKALAC MW-100LM and NIKALAC MX-750LM (all of which are trade names, manufactured by Sanwa Chemical Ind. Co., Ltd.).

Preferred examples of the compound having at least two epoxy groups include Denacol EX-212L, Denacol EX-214L, Denacol EX-216L and Denacol EX-850L (all of which are manufactured by Nagase ChemteX Corporation), GAN and GOT (all of which are manufactured by Nippon Kayaku Co., Ltd.), Epikote 828, Epikote 1002, Epikote 1750, Epikote 1007, YX8100-BH30, E1256, E4250 and E4275 (all of which are manufactured by Japan Epoxy Resin Co., Ltd.), Epiclon EXA-9583 and HP4032 (all of which are manufactured by Dainippon Ink and Chemicals Co., Ltd.), VG3101 (manufactured by Mitsui Chemicals Inc.), TEPIC S, TEPIC G and TEPIC P (all of which are manufactured by Nissan Chemical Corporation), NC6000 (manufactured by Nippon Kayaku Co., Ltd.), Epitohto YH-434L (manufactured by Tohto Kasei Co., Ltd.), and EPPN502H and NC3000 (manufactured by Nippon Kayaku Co., Ltd.).

Preferred examples of the compound having at least two oxetanyl groups include Ethanacol EHO, Ethanacol OXBP, Ethanacol OXTP, Ethanacol OXMA (all of which are manufactured by Ube Industries, Ltd.), an oxetanized phenol novolak resin and the like.

Two or more thermal crosslinking agents may be used in combination.

The content of the thermal crosslinking agent is preferably 0.1 part by mass or more and 30 parts by mass or less based on 100 parts by mass of the component (B). When the content of the thermal crosslinking agent is 0.1 part by mass or more and 30 parts by mass or less, the chemical resistance and hardness of the film after firing or curing can be enhanced, and the storage stability of the photosensitive resin composition is also excellent.

The photosensitive resin composition used in the present invention may further contain an adhesion improver. Examples of the adhesion improver include silane coupling agents such as vinyltrimethoxysilane, vinyltriethoxysilane, epoxycyclohexylethyltrimethoxysilane, 3-glycidoxypropyltrimethoxysilane, 3-glycidoxypropyltriethoxysilane, p-styryltrimethoxysilane, 3-aminopropyltrimethoxysilane, 3-aminopropyltriethoxysilane and N-phenyl-3-aminopropyltrimethoxysilane, titanium chelating agents, aluminum chelating agents, compounds obtained by reacting an aromatic amine compound with an alkoxy group-containing silicon compound. Two or more of these adhesion improvers may be contained. By containing these adhesion improvers, it is possible to improve the adhesion to a base material such as a silicon wafer, ITO, SiO₂ or silicon nitride when a photosensitive resin film is developed. It is also possible to enhance the resistance to oxygen plasma and UV ozone treatments used for washing. The content of the adhesion improver is preferably 0.1 part by mass or more and 10 parts by mass or less based on 100 parts by mass of the component (B).

The photosensitive resin composition used in the present invention further contains a surfactant for the purpose of improving the wettability with the substrate and improving the thickness uniformity of the photosensitive resin film, if necessary. Commercially available compounds can be used as the surfactant, and specifically, examples of the silicone-based surfactant include SH series, SD series and ST series of Dow Corning Toray Silicone Co., Ltd., BYK series of BYK-Chemie Japan K.K., KP series of Shin-Etsu Silicones, Disfoam series of NOF Corporation, and TSF series of Toshiba Silicone Co., Ltd.; examples of the fluorine-based surfactant include “Megafac (registered trademark)” series of DAINIPPON INK AND CHEMICALS, INC, Fluorad series of Sumitomo 3M Limited, “Surflon (registered trademark)” series and the “AsahiGuard (registered trademark)” series of Asahi Glass Co., Ltd., EF series of Shin-Akita Chemical Co., Ltd. and PolyFox series of OMNOVA Solutions Inc.; and examples of the surfactant composed of an acrylic and/or methacrylic polymer(s) include Polyflow series of Kyoeisha Chemical Co., Ltd. and “Disparlon (registered trademark)” series of Kusumoto Chemicals Ltd.

The content of the surfactant is preferably 0.001 part by mass or more and 1 part by mass or less based on 100 parts by mass of the component (B).

The photosensitive resin composition used in the present invention may further contain a compound having a phenolic hydroxyl group for the purpose of supplementing the alkaline developability of the photosensitive resin composition, if necessary. Examples of the compound having a phenolic hydroxyl group include Bis-Z, BisOC-Z, BisOPP-Z, BisP-CP, Bis26X-Z, BisOTBP-Z, BisOCHP-Z, BisOCR-CP, BisP-MZ, BisP-EZ, Bis26X-CP, BisP-PZ, BisP-IPZ, BisCRIPZ, BisOCP-IPZ, BisOIPP-CP, Bis26X-IPZ, BisOTBP-CP, TekP-4HBPA (tetrakisP-DO-BPA), TrisPHAP, TrisP-PA, TrisP-PHBA, TrisP-SA and TrisOCR-PA, (trade name, manufactured by Honshu Chemical Industry Co., Ltd.), BIR-OC, BIP-PC, BIR-PC, BIR-PTBP, BIR-PCHP, BIP-BIOC-F, 4PC, BIR-BIPC-F and TEP-BIP-A (trade name, manufactured by ASAHI YUKIZAI CORPORATION), 1,4-dihydroxynaphthalene, 1,5-dihydroxynaphthalene, 1,6-dihydroxynaphthalene, 1,7-dihydroxynaphthalene, 2,3-dihydroxynaphthalene, 2,6-dihydroxynaphthalene, 2,7-dihydroxynaphthalene, 2,4-dihydroxyquinoline, 2,6-dihydroxyquinoline, 2,3-dihydroxyquinoxaline, anthracene-1,2,10-triol, anthracene-1,8,9-triol, 8-quinolinol and the like. By containing these compounds having a phenolic hydroxyl group, the photosensitive resin composition thus obtained is hardly dissolved in an alkaline developer before exposure, and is easily dissolved in the alkaline developing solution when exposed, so that film loss is reduced and it becomes easy to develop within a short time. Therefore, the sensitivity is likely to be improved.

The content of such a compound having a phenolic hydroxyl group is preferably 1 part by mass or more and 40 parts by mass or less based on 100 parts by mass of the component (B).

Examples of the method for producing a photosensitive resin composition includes a method in which the component (A) is directly dispersed in a solution containing the component (B), the component (C) and the photoacid generator (D) using a disperser, a method in which the component (A) is dispersed in the component (C) using a disperser to prepare a colored dispersion liquid, and then the colored dispersion liquid is with the component (B) and the photoacid generator (D) and the like.

Examples of the disperser include ball mills, sand grinders, three roll mills and high speed impact mills. Of these dispersers, bead mills are preferable from the viewpoint of the efficient dispersion and the fine dispersion. Examples of the bead mills include coball mills, basket mills, pin mills, dyno mills and the like. Examples of the bead used in the bead mill include a titania bead, a zirconia bead, a zircon bead and the like. The bead used in the bead mill preferably has a bead size of 0.03 to 1.0 mm. When the component (A) has a small primary particle size and a small particle size of the secondary particle formed by aggregation of the primary particle, it is preferable to use a fine bead having a size of 0.03 to 0.10 mm.

In this case, a bead mill provided with a centrifugal separator capable of separating the fine bead from the dispersion liquid is preferable. Meanwhile, when the component (A) containing coarse particles having about a submicron size is dispersed, it is preferable to use a bead having a size of 0.10 mm or more since sufficient crushing force is obtained. The bead size can be calculated by measuring the equivalent circle diameter of 100 beads randomly selected by microscopic observation to obtain a number average value thereof.

A cured film can be obtained by curing the photosensitive resin composition of the present invention. As a method for curing a photosensitive resin composition, specifically, it is preferable to use a thermal curing method mentioned later.

The method for curing a photosensitive resin composition of the present invention to form a cured film will be described in detail below.

The method for producing a cured film includes a step of applying a photosensitive resin composition to form a photosensitive resin film, a step of drying the photosensitive resin film, a step of exposing the dried photosensitive resin film, a step of developing the exposed photosensitive resin film, and a step of thermally curing the photosensitive resin film.

The details of each step will be described below. In the present invention, among the films formed on the substrate, the film between the time when the photosensitive resin composition is applied on the substrate and the time before thermal curing is called a photosensitive resin film, and the film after thermal curing is called a cured film.

First, the step of applying a photosensitive resin composition to form a photosensitive resin film will be described. In this step, the photosensitive resin composition of the present invention is applied on a substrate by a spin coating method, a slit coating method, a dip coating method, a spray coating method, a printing method or the like to obtain a photosensitive resin film. Of these, the slit coat method is preferably used. The coating speed in the slit coating method is generally in the range of 10 mm/sec to 400 mm/sec. The thickness of the photosensitive resin film varies depending on the solid content concentration, viscosity and the like of the photosensitive resin composition. Usually, the photosensitive resin composition is applied so that the thickness after drying is preferably 0.1 to 10 μm, and more preferably 0.3 to 3 μm.

Examples of the substrate include glass, quartz, silicon, ceramic, plastic, and those in which electrodes made of ITO, Cu, and Ag are partially formed thereon.

Before coating, the substrate to be coated with the photosensitive resin composition may be subjected to a pretreatment with the above-mentioned adhesion improver in advance. Examples thereof include a method in which the surface of the base material is treated with a solution prepared by dissolving 0.5 to 20% by mass of the adhesion improver in a solvent such as isopropanol, ethanol, methanol, water, tetrahydrofuran, propylene glycol monomethyl ether acetate, PGME, ethyl lactate or diethyl adipate. Examples of the method for treating the surface of the base material include methods such as spin coating, slit die coating, bar coating, dip coating, spray coating and steam treatment.

Subsequently, the step of drying the photosensitive resin film will be described. In this step, the photosensitive resin film obtained by applying the photosensitive resin composition is dried. Drying in this step means vacuum drying or heat drying. Both vacuum drying and heat drying may be carried out, or only one of them may be carried out.

Heat drying will be described. This step is also called prebaking. A hot plate, an oven, infrared rays, etc. are used for heating. The heating temperature varies depending on the type and purpose of the photosensitive resin film, and heat drying is preferably performed at the temperature in the range of 50° C. to 180° C. for 1 minute to several hours.

Subsequently, the step of exposing the photosensitive resin film will be described. In this step, in order to form a pattern from the thus obtained photosensitive resin film, the photosensitive resin film is exposed by irradiation with actinic rays through a mask having a desired pattern. Examples of actinic rays used for exposure include ultraviolet rays, visible rays, electron beams, X-rays and the like. In the present invention, i-rays (365 nm), h-rays (405 nm) or g-rays (436 nm) of mercury lamps are preferably used. When the photosensitive resin film has positive photosensitivity, the exposed area is dissolved in the developing solution.

Subsequently, the step of developing the exposed photosensitive resin film will be described. In this step, after exposure, a desired pattern is formed by removing the exposed area in the case of a positive type using a developing solution. The developing solution is preferably an aqueous solution of compounds which exhibit alkalinity, such as tetramethylammonium hydroxide (hereinafter referred to as TMAH), diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, dimethylaminoethyl methacrylate, cyclohexylamine, ethylenediamine and hexamethylenediamine. In some cases, it is possible to add polar solvents such as N-methyl-2-pyrrolidone, N,N-dimethylformamide, N,N-dimethylacetamide, dimethyl sulfoxide, γ-butyrolactone and dimethylacrylamide; alcohols such as methanol, ethanol and isopropanol; esters such as ethyl lactate and propylene glycol monomethyl ether acetate; ketones such as cyclopentanone, cyclohexanone, isobutyl ketone and methyl isobutyl ketone alone or in combination of several types thereof to these aqueous alkaline solution. The developing method can be a method such as spraying, paddle, dipping, ultrasonic wave or the like.

Subsequently, it is preferable to subject the pattern formed by development to a rinsing treatment with distilled water. Here, it is also possible to add alcohols such as ethanol and isopropyl alcohol, and esters such as ethyl lactate and propylene glycol monomethyl ether acetate to distilled water for a rinsing treatment.

Subsequently, the step of thermally curing the photosensitive resin film will be described. In this step, since components having low heat resistance can be removed by thermal curing, the heat resistance and chemical resistance of the obtained cured film can be improved. In particular, when the photosensitive resin composition of the present invention contains an alkaline soluble resin selected from a polyimide precursor and a polybenzoxazole precursor, or an alkaline soluble resin which is a copolymer of them and polyimide, an imide ring or an oxazole ring can be formed by thermal curing, thus enabling an improvement in heat resistance and chemical resistance. When the photosensitive resin composition of the present invention contains a compound having at least two of an alkoxymethyl group, a methylol group, an epoxy group or oxytanyl group, the thermal crosslinking reaction can be allowed to proceed in the thermally curing step, thus enabling an improvement in heat resistance and chemical resistance of the thus obtained cured film.

The heating temperature is preferably 150 to 300° C., and the heating time is preferably 0.25 to 5 hours. The heating temperature may be changed continuously or stepwise.

The organic EL display device of the present invention includes at least a substrate, a first electrode, a second electrode, light emitting pixels, a planarization layer and a pixel division layer. The organic EL display device of the present invention is preferably an active matrix type organic EL display device having a plurality of light emitting pixels formed in a matrix. The active matrix type display device has a planarization layer on a TFT substrate in which TFT is formed on a substrate such as glass. Further, the display device has a first electrode provided on the planarization layer so as to cover at least the lower part of the light emitting pixel. The display device has a light emitting pixel on the upper part of the first electrode. The display device also has a second electrode provided to cover at least the top of the light emitting pixel. The plurality of light emitting pixels are divided by an insulating pixel division layer. The cured film obtained from the photosensitive resin composition of the present invention can be suitably used for the planarization layer and the pixel division layer.

Since the photosensitive resin composition of the present invention can form a pattern having high definition and no residue in the opening, it can also be used for a solid-state imaging device, a micro LED, a colored partition for a mini LED display device, and a black matrix and a black column spacer used in a color filter for a liquid crystal display device.

### EXAMPLES

Hereinafter, the present invention will be described in detail with reference to Examples and Comparative Examples, but the aspects of the present invention are not limited thereto.

### <Evaluation Method>[Crystallite Size of Zirconium Nitride Particle Powder]

The zirconium nitride compound particles Zr-1 to Zr-3 were packed in an aluminum standard sample holder, and the X-ray diffraction spectrum was measured by wide-angle X-ray diffraction using RU-200R manufactured by Rigaku Corporation and using a CuKα1 ray as an X-ray source. The measurement conditions were as follows: the output was 50 kV/200 mA, the slit system was 1°−1°−0.15 mm−0.45 mm, the measurement step (2θ) was 0.02°, and the scan speed was 2°/min.

The diffraction angle and the half width of the peak derived from the ZrN (111) plane observed in the vicinity of a diffraction angle 2θ=33.8° was measured, and the size of crystallite constituting the particle was determined using the Scherrer equation shown in Formula (1).

$$\begin{matrix}[ Equation 1 ] & \\ Crystallite size ( nm ) = \frac{K λ}{β cos θ} & ( 1 )\end{matrix}$$

### [Crystallite Size of Zirconium Nitride Particles in Colored Dispersion Liquid]

The colored pigment dispersion liquid obtained in each Production Example was applied on an alkaline-free glass substrate OA-10G (manufactured by Nippon Electric Glass Co., Ltd.) by spin coating using a spin coater (MS-A100; manufactured by Mikasa Co., Ltd.) and then prebaked at 100° C. for 120 seconds using a hot plate (SCW-636; manufactured by Dainippon Screen Mfg. Co., Ltd.) to fabricate a prebaked film having a thickness of 3.0 μm.

Regarding the prebaked film thus obtained, the X-ray diffraction spectrum was measured by wide-angle X-ray diffraction using RU-200R manufactured by Rigaku Corporation and using a CuKα1 ray as an X-ray source. The measurement conditions were as follows: the output was 50 kV/200 mA, the slit system was 1°−1°−0.15 mm−0.45 mm, the measurement step (20) was 0.02°, and the scan speed was 0.4°/min.

The diffraction angle and the half width of the peak derived from the ZrN (111) plane observed in the vicinity of a diffraction angle 2θ=33.8° was measured, and the size of crystallite constituting the zirconium nitride particles in the resin film was determined using the above-mentioned Scherrer equation.

### [Crystallite Size of Zirconium Nitride Particle in Cured Film]

Regarding the cured film obtained in each Example and Comparative Example, the X-ray diffraction spectrum was measured by wide-angle X-ray diffraction using RU-200R manufactured by Rigaku Corporation and using a CuKα1 ray as an X-ray source. The measurement conditions were as follows: the output was 50 kV/200 mA, the slit system was 1°−1°−0.15 mm−0.45 mm, the measurement step (2θ) was 0.02°, and the scan speed was 2°/min.

The diffraction angle and the half width of the peak derived from the ZrN (111) plane observed in the vicinity of a diffraction angle 2θ=33.8° was measured, and the size of crystallite constituting the particles in the resin film was determined using the Scherrer equation shown in Formula (1).

### [Dispersion Stability]

The initial viscosity of the photosensitive resin composition obtained in each Example and Comparative Example, and the initial viscosity after standing at 23° C. for 7 days were measured using an E type viscometer RE105L (manufactured by Toki Sangyo Co., Ltd.) so that the temperature of the measurement sample became 25° C. It was judged that the smaller the viscosity change rate after the lapse of 7 days relative to the initial viscosity, the more the dispersion stability of the pigment is excellent.

### Evaluation

A: Less than viscosity change rate ±5%
B: Viscosity change rate ±5% or more and less than ±10%
C: Viscosity change rate ±10% or more and less than ±20%
D: Viscosity change rate ±20% or more and less than ±50%
E: Viscosity change rate ±50% or more

### [Sensitivity]

The presence or absence of the residue in the opening of the cured film obtained in each Example and Comparative Example was observed by an optical microscope. The minimum exposure dose at which the aperture width has the same line width (50 μm) as the mask design was regarded as the sensitivity.

### Evaluation

A: Less than 100 mJ/cm²
B: 100 mJ/cm² or more and less than 200 mJ/cm²
C: 200 mJ/cm² or more and less than 500 mJ/cm²
D: 500 mJ/cm² or more

### [Light Shielding Property]

Using a densitometer (361T visual; manufactured by X-Rite Inc.), the incident light intensity and transmitted light intensity onto and from the cured film obtained in each Example and Comparative Example were measured, and the OD value of the cured film was calculated by the following Formula (3).

OD value=log₁₀(I₀/I) Formula (3)

I₀: Incident light intensity

I: Transmitted light intensity

Using a contact type thickness meter (DEKTAK150, manufactured by ULVAC, Inc.), the thickness of the cured film was measured and OD value/thickness was calculated, thus evaluating the light-shielding property per 1 μm of each cured film.

### [Amount of Developed Film Loss in Unexposed Area]

The thickness of the photosensitive resin film obtained in each Example and Comparative Example is measured and is regarded as the thickness after drying. After developing the photosensitive resin film with an aqueous 2.38% s by mass TMAH solution as an alkaline developing solution for 60 seconds, the thickness is measured, and this value is regarded as the thickness after development. The amount of developed film loss in the unexposed area is represented by (thickness after drying)−(thickness after development). It was judged that the smaller the amount of developed film loss in the unexposed area, it becomes easier to form a pattern with a desired thickness, leading to suppression of the residue in the opening and excellent workability.

### [Residue in Opening]

The opening of the patterned substrate obtained in each Example and Comparative Example was observed by an optical microscope, and it was evaluated whether or not the residue is present in the opening.

### Evaluation

A: No residue per 50 μm square
B: Less than 10 residues per 50 μm square
C: 10 or more and less than 20 residues per 50 μm square
D: 20 or more residues per 50 μm square

### [Organic EL Display Device Visibility]

The organic EL display device fabricated in each Example and Comparative Example was allowed to emit light by direct-current drive at 10 mA/cm², and the luminance (Y′) in the case of irradiating the pixel division layer part with external light, and the luminance (Y₀) in the case of irradiating the part with no external light were measured. As an index for reduction in external light reflection, the contrast was calculated by the following Formula.

Contrast=Y₀/Y′

The higher the contrast, the better the visibility, and the evaluation was made according to the following criteria.

### Evaluation

### A: Contrast is 0.95 to 1.00.

### B: Contrast is 0.90 to 0.94.

### C: Contrast is 0.80 to 0.89.

### D: Contrast is 0.70 to 0.79.

### E: Contrast is 0.50 to 0.69.

### F: Contrast is 0.01 to 0.49.

### [Organic EL Display Device Device in Off-Pixel State]

A total of 20 organic EL display devices were fabricated by the method of each Example and Comparative Example, and a display test was performed and the number of devices in an off-pixel state was observed. The smaller the number of devices in an off-pixel state, the better, and the evaluation was made according to the following criteria.

### Evaluation

A: All devices are in an on-pixel state.
B: The number of devices in an off-pixel state is 1 to 4.
C: The number of devices in an off-pixel state is 5 to 10.
D: The number of devices in an off-pixel state is 10 or more.

### [Organic EL Display Device Darkspots]

Regarding organic EL display device fabricated in each Example and Comparative Example, 10 light emitting pixel portions located in the center of the device were magnified and displayed on a monitor at a magnification of 50 times for observation, and then the number of local non-light emitting sites having a major axis of 0.1 μm or more in each opening was counted. The smaller the average number of local non-light emitting sites observed per opening, the better, and the evaluation was made based on the following criteria.

### Evaluation

A: No darkspots can be observed.
B: Less than 5 darkspots can be observed.
C: Five (5) or more and less than 10 darkspots can be observed.
D: Ten (10) or more and less than 15 darkspots can be observed.
E: Fifteen (15) or more darkspots can be observed.

### [Organic EL Display Device Long-Term Reliability]

The organic EL display device fabricated in each Example and Comparative Example was placed on a hot plate heated to 80° C. in a state that the light emitting surface faced upward, and then irradiated with UV rays having a wavelength of 365 nm and an illuminance of 0.6 kmW/cm². Immediately after the irradiation (0 hour), and after the lapse of 1,000 hours, the organic EL display device was driven with direct current of 0.625 mA to emit light, and the ratio of the area of the light-emitting portion to the area of the light emitting pixel (pixel light-emitting area ratio) was measured. Using this evaluation method, when the pixel light-emitting area ratio after the lapse of 1,000 hours is 80% or more, it is judged that the long-term reliability is excellent, and when the pixel light-emitting area ratio is 90% or more, it is more preferable.

### Evaluation

A: Pixel light-emitting area ratio is 95% or more.
B: Pixel light-emitting area ratio is 90% or more and less than 95%.
C: Pixel light-emitting area ratio is 80% or more and less than 90%.
D: Pixel light-emitting area ratio is 70% or more and less than 80.
E: Pixel light-emitting area ratio is less than 70%.

### Production Examples

### Synthesis Example 1: Synthesis of Hydroxyl Group-Containing Diamine Compound (HA)

18.3 g (0.05 mol) of 2,2-bis(3-amino-4-hydroxyphenyl)hexafluoropropane (hereinafter referred to as BAHF) was dissolved in 100 mL of acetone and 17.4 g (0.3 mol) of propylene oxide, followed by cooling to −15° C. To the resulting solution, a solution prepared by dissolving 20.4 g (0.11 mol) of 3-nitrobenzoyl chloride in 100 mL of acetone was added dropwise. After completion of the dropwise addition, the resulting solution was stirred at −15° C. for 4 hours and the temperature was returned to room temperature. The precipitated white solid was filtered out and vacuum-dried at 50° C.

In a 300 mL stainless steel autoclave, 30 g of the obtained white solid was charged and dispersed in 250 mL of methyl cellosolve, and then 2 g of 5% palladium-carbon was added. Hydrogen was introduced thereinto with a balloon and the reduction reaction was performed at room temperature. After about 2 hours, the reaction was completed by confirming that the balloon did not deflate any more. After completion of the reaction, the palladium compound as a catalyst was removed by filtration, and the filtrate was concentrated by a rotary evaporator to obtain a hydroxyl group-containing diamine compound (hereinafter referred to as HA).

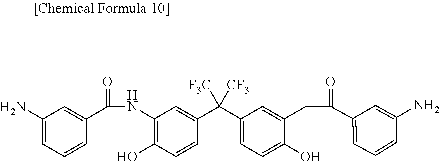 [SMILES: Nc1cccc(C(=O)Cc2cc(C(c3ccc(O)c(NC(=O)c4cccc(N)c4)c3)(C(F)(F)F)C(F)(F)F)ccc2O)c1]

### Synthesis Example 2: Alkaline Soluble Resin P-1

Under a dry nitrogen gas stream, 21.2 g (0.035 mol) of HA obtained in Synthesis Example 1, 7.0 g (0.035 mol) of 4,4′-diaminodiphenyl ether (hereinafter referred to as DAE), and 1.2 g (0.005 mol) of bis(3-aminopropyl)tetramethyldisiloxane (hereinafter referred to as SiDA) were dissolved in 400 g of N-methyl-2-pyrrolidone (hereinafter referred to as NMP). To the resulting solution, 31.0 g (0.10 mol) of 4,4′-oxydiphthalic dianhydride (hereinafter referred to as ODPA) was added together with 50 g of NMP, followed by stirring at 40° C. for 1 hour. Thereafter, 5.5 g (0.050 mol) of 3-aminophenol (hereinafter referred to as MAP) was added, followed by stirring at 40° C. for 1 hour. After completion of the stirring, the solution was cooled to room temperature and the solution was poured into 3 L of water to obtain a white precipitate. This precipitate was collected by filtration, washed with water three times and then dried by a vacuum dryer at 50° C. for 72 hours to obtain an alkaline soluble resin (P-1) composed of a polyimide precursor. The alkaline soluble resin (P-1) included a structural unit represented by general formula (1) in which p=0, q=2, and R⁴ is a hydroxyl group, and a structural unit represented by general formula (2) in whichr=2, s=2, R⁷ is a carboxy group, and R⁸ is hydroxyl group, and had an acid equivalent of 220 g/mol.

### Synthesis Example 3: Alkaline Soluble Resin P-2

Under a dry nitrogen gas stream, 21.2 g (0.035 mol) of HA obtained in Synthesis Example 1, 7.0 g (0.035 mol) of DAE and 1.2 g (0.005 mol) of SiDA were dissolved in 400 g of NMP. To the resulting solution, 31.0 g (0.10 mol) of ODPA was added together with 50 g of NMP, followed by stirring at 40° C. for 1 hour. Thereafter, 5.5 g (0.050 mol) of MAP was added, followed by stirring at 40° C. for 1 hour. Further, a solution prepared by dissolving 8.3 g (0.07 mol) of N,N-dimethylformamide dimethyl acetal (hereinafter referred to as DFA) in 10 g of NMP was added dropwise over 10 minutes. After completion of the dropwise addition, the solution was stirred at 40° C. for 3 hours. After completion of the stirring, the solution was cooled to room temperature and the solution was poured into 3 L of water to obtain a white precipitate. This precipitate was collected by filtration, washed with water three times and then dried by a vacuum dryer at 50° C. for 72 hours to obtain an alkaline soluble resin (P-2) composed of a polyimide precursor. The alkaline soluble resin (P-2) included a structural unit represented by general formula (1) in which p=0, q=1 or 2, and R⁴ is a hydroxyl group, and a structural unit represented by general formula (2) in which r=1 or 2, s=1 or 2, R⁷ is a carboxy group, and R⁸ is a hydroxyl group, and had an acid equivalent of 275 g/mol.

### Synthesis Example 4: Alkaline Soluble Resin P-3

In the same manner as in Synthesis Example 3, the amount of DFA to be charged was set at 13.1 g (0.11 mol) to obtain an alkaline soluble resin (P-3) composed of a polyimide precursor. The alkaline soluble resin (P-3) included a structural unit represented by general formula (1) in which p=0, q=1 or 2, and R⁴ is a hydroxyl group, and a structural unit represented by general formula (2) in whichr=1 or 2, s=1 or 2, R⁷ is a carboxy group, and R⁸ is a hydroxyl group, and had an acid equivalent of 329 g/mol.

### Synthesis Example 5: Alkaline Soluble Resin P-4

In the same manner as in Synthesis Example 3, the amount of DFA to be charged was set at 16.7 g (0.14 mol) to obtain an alkaline soluble resin (P-4) composed of a polyimide precursor. The alkaline soluble resin (P-4) included a structural unit represented by general formula (1) in which p=0, q=1 or 2, and R⁴ is a hydroxyl group, and a structural unit represented by general formula (2) in whichr=1 or 2, s=1 or 2, R⁷ is a carboxy group, and R⁸ is a hydroxyl group, and had an acid equivalent of 366 g/mol.

### Synthesis Example 6: Alkaline Soluble Resin P-5

In the same manner as in Synthesis Example 3, the amount of DFA to be charged was set at 19.1 g (0.16 mol) to obtain an alkaline soluble resin (P-5) composed of a polyimide precursor. The alkaline soluble resin (P-5) included a structural unit represented by general formula (1) in which p=0, q=1 or 2, and R⁴ is a hydroxyl group, and a structural unit represented by general formula (2) in whichr=1 or 2, s=1 or 2, R⁷ is a carboxy group, and R⁸ is a hydroxyl group, and had an acid equivalent of 411 g/mol.

### Synthesis Example 7: Alkaline Soluble Resin P-6

In the same manner as in Synthesis Example 3, the amount of DFA to be charged was set at 22.6 g (0.19 mol) to obtain an alkaline soluble resin (P-6) composed of a polyimide precursor. The alkaline soluble resin (P-6) included a structural unit represented by general formula (1) in which p=0, q=1 or 2, and R⁴ is a hydroxyl group, and a structural unit represented by general formula (2) in whichr=1 or 2, s=1 or 2, R⁷ is a carboxy group, and R⁸ is a hydroxyl group, and had an acid equivalent of 471 g/mol.

### Synthesis Example 8: Alkaline Soluble Resin P-7

Under a dry nitrogen gas stream, 29.3 g (0.08 mol) of BAHF and 1.2 g (0.05 mol) of SiDA were dissolved in 400 g of NMP. To the resulting solution, 31.0 g (0.10 mol) of ODPA was added together with 50 g of NMP, followed by stirring at 40° C. for 1 hour. Thereafter, 3.3 g (0.03 mol) of MAP was added, followed by stirring at 40° C. for 1 hour and further stirring at 150° C. for 5 hours. After completion of the stirring, the solution was cooled to room temperature and the solution was poured into 3 L of water to obtain a white precipitate. This precipitate was collected by filtration, washed with water three times and then dried by a vacuum dryer at 50° C. for 72 hours to obtain an alkaline soluble resin (P-7) composed of a polyimide resin in which a carboxy group derived from polyamic acid is absent and imidization went to 100% completion. The alkaline soluble resin (P-7) included a structural unit represented by general formula (1) in which p=0, q=2, and R⁴ is a hydroxyl group, and had an acid equivalent of 341 g/mol.

### Synthesis Example 9: Alkaline Soluble Resin P-8

Under a dry nitrogen gas stream, 0.08 mol of a mixture of a dicarboxylic acid derivative obtained by reacting 35.3 g (0.09 mol) of 2,2-bis(2-carboxyphenyl)hexafluoropropane with 21.6 g (0.16 mol) of 1-hydroxy-1,2,3-benzotriazole, and 36.7 g (0.10 mol) of BAHF were dissolved in 285 g of NMP, followed by a reaction at 75° C. for 12 hours. Subsequently, a solution prepared by dissolving 5.5 g (0.02 mol) of 3-carboxyphenol in 35 g of NMP was added, followed by stirring for 12 hours to complete the reaction. The solution was cooled to room temperature and the solution was poured into 3 L of water to obtain a white precipitate. This precipitate was collected by filtration, washed with water three times and then dried by a vacuum dryer at 50° C. for 72 hours to obtain an alkaline soluble resin (P-8) composed of an polybenzoxazole precursor, which has an acid equivalent of 339 g/mol.

### Synthesis Example 10: Alkaline Soluble Resin P-9

In the same manner as in P-1, 25.6 g (0.07 mol) of BAHF, 1.2 g (0.005 mol) of SiDA, 31.0 g (0.10 mol) of ODPA and 5.5 g (0.050 mol) of MAP were used as the monomers to be charged to obtain an alkaline soluble resin (P-9) composed of a polyimide precursor. The alkaline soluble resin (P-9) included a structural unit represented by general formula (1) in which p=0, q=2, and R⁴ is a hydroxyl group, and a structural unit represented by general formula (2) in which r=2, s=2, R⁷ is a carboxy group, and R⁸ is a hydroxyl group, and had an acid equivalent of 170 g/mol.

### Synthesis Example 11: Alkaline Soluble Resin P-10

An alkaline soluble resin (P-10) was obtained by the method mentioned in Synthesis Example 2 of WO 2019/059359. The alkaline soluble resin (P-10) included a structural unit represented by general formula (1) in which p=0, q=1 or 2, and R⁴ is a hydroxyl group, and a structural unit represented by general formula (2) in which r=1 or 2, s=1 or 2, R⁷ is a carboxy group, and R⁸ is a hydroxyl group, and had an acid equivalent of 550 g/mol.

### Synthesis Example 11

A methyl methacrylate/methacrylic acid/styrene copolymer (weight ratio of 30/40/30) was synthesized by the method mentioned in Example 1 of JP 3120476 B3, and then 40 parts by weight of GMA was added, followed by reprecipitation with purified water, filtration and further drying to obtain an acrylic copolymer (P-11) having a weight-average molecular weight (Mw) of 10,000 and an acid value of 110 (mgKOH/g).

### Synthesis Example 12: Quinonediazide Compound (D-1)

Under a dry nitrogen gas stream, 21.22 g (0.05 mol) of TrisP-PA (trade name, manufactured by Honshu Chemical Industry Co., Ltd.) and 36.27 g (0.135 mol) of 5-naphthoquinonediazidesulfonyl acid chloride were dissolved in 450 g of 1,4-dioxane, and the temperature was adjusted to room temperature. To this resulting solution, 15.18 g of triethylamine mixed with 50 g of 1,4-dioxane was added dropwise so that the temperature inside the system was not raised to 35° C. or higher. After dropwise addition, the resulting solution was stirred at 30° C. for 2 hours. The triethylamine salt was filtered out and the filtrate was poured into water. Then, the precipitate was collected by filtration. This precipitate was dried by a vacuum dryer to obtain a quinonediazide compound (D-1) represented by Formula shown below.

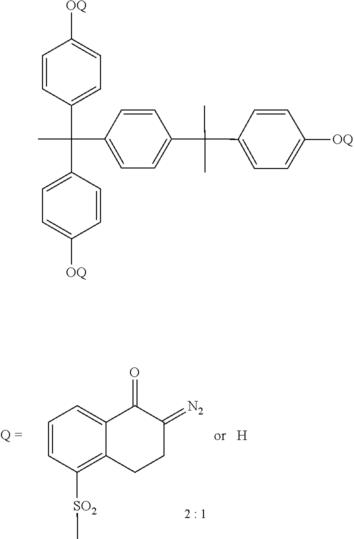

### Production Example 1 Production of Colored Pigment Dispersion Liquid (DB-1)

In a tank, 200 g of zirconium nitride particles (ZrN-1) in which a crystallite size in a powder state is 30 nm, produced by a thermal plasma method (manufactured by NISSHIN ENGINEERING INC.), 50 g of an alkaline soluble resin (P-1), and 1,000 g of γ-butyrolactone were charged, followed by stirring with a homomixer for 20 minutes to obtain a preliminary dispersion liquid. The obtained preliminary dispersion liquid was supplied to a disperser Ultra Apex Mill manufactured by HIROSHIMA METAL & MACHINERY equipped with a centrifugal separator filled with 75% by volume of a 0.05 mmφ zirconia bead, followed by dispersion for 3 hours at a rotational speed of 10 m/s to obtain a colored pigment dispersion liquid (DB-1) having a solid content concentration of 20% by weight, a colorant/resin (mass ratio) of 80/20, and a crystallite size of zirconium nitride particles of 15 nm.

### Production Examples 2 to 10 Production of Colored Pigment Dispersion Liquids (DB-2 to DB-10)

In the same manner as in DB-1, (P-2) to (P-10) were respectively used as the alkaline soluble resin to be charged to obtain colored pigment dispersion liquids (DB-2) to (DB-10).

### Production Example 11 Production of Colored Pigment Dispersion Liquid (DB-11)

In the same manner as in DB-1, composite fine particles ZrN—Al composed of zirconium nitride and aluminum produced by the method mentioned in Production Example 3 of WO2019/059359 (manufactured by NISSHIN ENGINEERING INC., Al content=4% by weight) was used as the pigment to be charged, and (P-4) was used as the alkaline soluble resin to obtain a colored pigment dispersion liquid (DB-11).

### Production Example 12 Production of Colored Pigment Dispersion Liquid (DB-12)

In the same manner as in DB-1, γ valerolactone was used as the organic solvent to be charged, and (P-4) was used as the alkaline soluble resin to obtain a colored pigment dispersion liquid (DB-12).

### Production Example 13 Production of Colored Pigment Dispersion Liquid (DB-13)

In the same manner as in DB-1, 1,000 g of PGME was used as the organic solvent to be charged, and (P-4) was used as the alkaline soluble resin to obtain a colored pigment dispersion liquid (DB-13).

### Production Example 14 Production of Colored Pigment Dispersion Liquid (DB-14)

In the same manner as in DB-1, 500 g of γ-butyrolactone and 500 g of PGME were used as the organic solvent to be charged, and (P-4) was used as the alkaline soluble resin to obtain a colored pigment dispersion liquid (DB-12).

### Production Example 15 Production of Colored Pigment Dispersion Liquid (DB-15)

In the same manner as in DB-1, zirconium nitride particles (ZrN-2) in which a crystallite size in a powder state is 15 nm, produced by a thermal plasma method (manufactured by NISSHIN ENGINEERING INC.) were used as the zirconium nitride particles to be charged, and (P-4) was used as the alkaline soluble resin to obtain a colored pigment dispersion liquid (DB-15) having a crystallite size of zirconium nitride particles of 4 nm.

### Production Example 16 Production of Colored Pigment Dispersion Liquid (DB-16)

In the same manner as in DB-1, (ZrN-2) was used as the zirconium nitride particles to be charged, (P-4) was used as the alkaline soluble resin, and the dispersion time was set at 2 hours to obtain a colored pigment dispersion liquid (DB-16) having a crystallite size of zirconium nitride particles of 8 nm.

### Production Example 17 Production of Colored Pigment Dispersion Liquid (DB-17)

In the same manner as in DB-1, (P-4) was used as the alkaline soluble resin to be charged, and the dispersion time was set at 2 hours to obtain a colored pigment dispersion liquid (DB-17) having a crystallite size of zirconium nitride particles of 20 nm.

### Production Example 18 Production of Colored Pigment Dispersion Liquid (DB-18)

In the same manner as in DB-1, (P-4) was used as the alkaline soluble resin to be charged, and the dispersion time was set at 1 hour to obtain a colored pigment dispersion liquid (DB-16) having a crystallite size of zirconium nitride particles of 25 nm.

### Production Example 19 Production of Colored Pigment Dispersion Liquid (DB-19)

In the same manner as in DB-1, 200 g of zirconium nitride particles, 25 g of an alkaline soluble resin (P-10), 25 g of “BYK” (registered trademark) 2200 (manufactured by BYK-Chemie GmbH), and 1,000 g of γ-butyrolactone were used to obtain colored pigment dispersion liquid (DB-19).

### Production Example 20 Production of Colored Pigment Dispersion Liquid (DB-20)

In the same manner as in DB-1, 200 g of zirconium nitride particles (ZrN-1), 25 g of an alkaline soluble resin (P-11), 25 g of “BYK” (registered trademark) 2200 (manufactured by BYK-Chemie GmbH), and 1,000 g of propylene glycol monomethyl ether acetate (hereinafter referred to as PGMEA) were used to obtain a colored pigment dispersion liquid (DB-20) having a crystallite size of zirconium nitride particles of 15 nm.

### Production Example 21 Production of Colored Dispersion Liquid (DB-21)

In the same manner as DB-20, (ZzN-2) was used as the zirconium nitride particles to be charged to obtain a colored pigment dispersion liquid (DB-21) having a crystallite size of zirconium nitride particles of 4 nm.

### Production Example 22 Production of Colored Dispersion Liquid (DB-22)

In the same manner as DB-20, (ZrN-2) was used as the zirconium nitride particles to be charged, and the dispersion time was set at 2 hours to obtain a colored pigment dispersion liquid (DB-22) having a crystallite size of zirconium nitride particles of 8 nm.

### Production Example 23 Production of Colored Dispersion Liquid (DB-23)

In the same manner as DB-20, the dispersion time was set at 2 hours to obtain a colored pigment dispersion liquid (DB-23) having a crystallite size of zirconium nitride particles of 20 nm.

### Production Example 24 Production of Colored Dispersion Liquid (DB-24)

In the same manner as DB-20, the dispersion time was set at 1 hour to obtain a colored pigment dispersion liquid (DB-24) having a crystallite size of zirconium nitride particles of 25 nm.

TABLE 1

| | | | | | | | | Characteristics |
|---|---|---|---|---|---|---|---|---|
| | Black dispersion liquid (mass ratio) | | | | | | | of dispersion |
| | | | | Component (C) | | | | liquid |
| Pigment | | | | | | Other | Pigment | Crystallite size |
| dispersion | Component | Component | Polymer | Component | Component | components | dispersion | of component |
| liquid | (A) | (B) | dispersant | (C-1) | (C-2) | (C) | time | (A) |
| DB-1 | ZrN-1 | P-1 | — | γ-Butyrolactone | — | — | 3 hours | 15 nm |
| | (16) | (4) | | (80) | | | | |
| DB-2 | ZrN-1 | P-2 | — | γ-Butyrolactone | — | — | 3 hours | 15 nm |
| | (16) | (4) | | (80) | | | | |
| DB-3 | ZrN-1 | P-3 | — | γ-Butyrolactone | — | — | 3 hours | 15 nm |
| | (16) | (4) | | (80) | | | | |
| DB-4 | ZrN-1 | P-4 | — | γ-Butyrolactone | — | — | 3 hours | 15 nm |
| | (16) | (4) | | (80) | | | | |
| DB-5 | ZrN-1 | P-5 | — | γ-Butyrolactone | — | — | 3 hour | 15 nm |
| | (16) | (4) | | (80) | | | | |
| DB-6 | ZrN-1 | P-6 | — | γ-Butyrolactone | — | — | 3 hours | 15 nm |
| | (16) | (4) | | (80) | | | | |
| DB-7 | ZrN-1 | P-7 | — | γ-Butyrolactone | — | — | 3 hours | 15 nm |
| | (16) | (4) | | (80) | | | | |
| DB-8 | ZrN-1 | P-8 | — | γ-Butyrolactone | — | — | 3 hours | 15 nm |
| | (16) | (4) | | (80) | | | | |
| DB-9 | ZrN-1 | P-9 | — | γ-Butyrolactone | — | — | 3 hours | 15 nm |
| | (16) | (4) | | (80) | | | | |
| DB-10 | ZrN-1 | P-10 | — | γ-Butyrolactone | — | — | 3 hours | 15 nm |
| | (16) | (4) | | (80) | | | | |
| DB-11 | ZrN-A1 | P-4 | — | γ-Butyrolactone | — | — | 3 hours | 15 nm |
| | (16) | (4) | | (80) | | | | |
| DB-12 | ZrN-1 | P-4 | — | γ-Valerolactone | — | — | 3 hours | 15 nm |
| | (16) | (4) | | (80) | | | | |
| DB-13 | ZrN-1 | P-4 | — | — | PGME | — | 3 hours | 15 nm |
| | (16) | (4) | | | (80) | | | |
| DB-14 | ZrN-1 | P-4 | — | γ-Butyrolactone | PGME | — | 3 hours | 15 nm |
| | (16) | (4) | | (40) | (40) | | | |
| DB-15 | ZrN-2 | P-4 | | γ-Butyrolactone | — | — | 3 hours | 14 nm |
| | (16) | (4) | | (80) | | | | |
| DB-16 | ZrN-2 | P-4 | | γ-Butytolactone | — | — | 2 hours | 8 nm |
| | (16) | (4) | | (80) | | | | |
| DB-17 | ZrN-1 | P-4 | | γ-Butytolactone | — | — | 2 hours | 20 nm |
| | (16) | (4) | | (80) | | | | |
| DB-18 | ZrN-1 | P-4 | | γ-Butyrolactone | — | — | 1 hour | 25 nm |
| | (16) | (4) | | (80) | | | | |
| DB-19 | ZrN-1 | P-10 | BYK-2200 | γ-Butyrolactone | — | — | 3 hours | 15 nm |
| | (16) | (2) | (2) | (80) | | | | |
| DB-20 | ZrN-1 | P-11 | BYK-2200 | | | PGMEA | 3 hours | 15 nm |
| | (16) | (2) | (2) | | | (80) | | |
| DB-21 | ZrN-2 | P-11 | BYK-2200 | — | — | PGMEA | 3 hours | 4 nm |
| | (16) | (2) | (2) | | | (80) | | |
| DB-22 | ZrN-2 | P-11 | BYK-2200 | — | — | PGMEA | 2 hours | 8 nm |
| | (16) | (2) | (2) | | | (80) | | |
| DB-23 | ZrN-1 | p-11 | BYK-2200 | — | — | PGMEA | 2 hours | 20 nm |
| | (16) | (2) | (2) | | | (80) | | |
| DB-24 | ZrN-1 | p-11 | BYK-2200 | — | — | PGMEA | 1 hour | 25 nm |
| | (16) | (2) | (2) | | | (80) | | |

### Example 1

To 93.8 g of a colored pigment dispersion liquid (DB-1), 50.5 g of an alkaline soluble resin (P-1), 17.0 g of a quinonediazide compound (D-1) as a photoacid generator, 13.6 g of a phenol compound bisphenol-AF (manufactured by Tokyo Chemical Industry Co., Ltd.), 0.2 g of a silicone-based surfactant “BYK” (registered trademark) 333 (manufactured by BYK-Chemie GmbH), 105.0 g of γ-butyrolactone, and 720.0 g of PGME were added to obtain a positive photosensitive resin composition (PB-1) having a total solid content concentration of 10% by mass and pigment/resin (mass ratio) of 15/85.

The obtained positive photosensitive resin composition (PB-1) was subjected to evaluation of the above [Dispersion Stability].

Subsequently, the obtained positive photosensitive resin composition (PB-1) was applied on an ITO substrate using a spinner (MS-A150) manufactured by Mikasa Co., Ltd. so that the obtained photosensitive resin film had the OD value of 1, and then dried by heating on a hot plate at 100° C. for 2 minutes to obtain a photosensitive resin film. Using a mask aligner (PEM-6M) manufactured by Union Optical Co., Ltd, the obtained photosensitive resin film was exposed to ultraviolet rays at 500 mJ/cm² as a maximum exposure dose, while reducing the exposure dose every 10 mJ/cm², through a positive mask (stripe design line width of 50 μm) manufactured by HOYA Corporation, and then developed with an aqueous 2.38% by mass TMAH solution as an alkaline developing solution for 60 seconds to obtain a patterned substrate with a photosensitive resin film formed in a predetermined pattern. Using the patterned substrate exposed at each exposure dose, [Sensitivity] was evaluated.

Subsequently, a photosensitive resin film was fabricated so that the OD value was 1 in the same manner as in the above evaluation of sensitivity, and [Amount of Developed Film Loss in Unexposed Area] was evaluated.

Subsequently, the obtained patterned substrate was fired in a hot air oven at 230° C. for 60 minutes to obtain a cured film (BK-1). Using the patterned substrate exposed at each exposure dose, [Light-Shielding Property] and [Residue in Opening] were evaluated.

To evaluate the storage stability of the positive photosensitive resin composition, the positive photosensitive resin composition was left to stand at 23° C. for 7 days, and then the patterned substrate was fabricated in the same manner as above and [Sensitivity] was evaluated.

### Examples 2 to 8

In the same manner as in Example 1, DB-2 to DB-8 were respectively used as the colored pigment dispersion liquid to be charged, and P-2 to P-8 were respectively used as the alkaline soluble resin to obtain positive photosensitive resin compositions (PB-2) to (PB-8) and cured films (BK-2) to (BK-8) thereof. The evaluation was performed in the same manner as in Example 1.

### Example 9

In the same manner as in Example 1, DB-11 was used as the type of the colored pigment dispersion liquid to be charged, and P-4 was used as the alkaline soluble resin to obtain a positive photosensitive resin composition (PB-9) and a cured film (BK-9) thereof. The evaluation was performed in the same manner as in Example 1.

### Example 10

In the same manner as in Example 1, DB-12 was used as the type of the colored pigment dispersion liquid to be charged, P-4 was used as the alkaline soluble resin, and γ-valerolactone was used in place of γ-butyrolactone as the organic solvent to obtain a positive photosensitive resin composition (PB-10) and a cured film (BK-10) thereof. The evaluation was performed in the same manner as in Example 1.

### Example 11

In the same manner as in Example 1, DB-14 was used as the type of the colored pigment dispersion liquid to be charged, P-4 was used as the alkaline soluble resin, and methyl lactate was used as the type of the organic solvent in place of PGME to obtain a positive photosensitive resin composition (PB-11) and a cured film (BK-11) thereof. The evaluation was performed in the same manner as in Example 1.

### Example 12

In the same manner as in Example 1, DB-14 was used as the type of the colored pigment dispersion liquid to be charged, P-4 was used as the alkaline soluble resin, and ethyl lactate was used as the type of the organic solvent in place of PGME to obtain a positive photosensitive resin composition (PB-12) and a cured film (BK-12) thereof. The evaluation was performed in the same manner as in Example 1.

### Example 13

In the same manner as in Example 1, DB-13 was used as the type of the colored pigment dispersion liquid to be charged, P-4 was used as the alkaline soluble resin, and PGME was used as the organic solvent was to obtain a positive photosensitive resin composition (PB-13) and a cured film (BK-13) thereof. The evaluation was performed in the same manner as in Example 1.

### Example 14

In the same manner as in Example 1, DB-14 was used as the type of the colored pigment dispersion liquid to be charged, P-4 was used as the alkaline soluble resin, 7.50 g of γ-butyrolactone was used as the organic solvent, and the amount of PGME was set at 817.5 g to obtain a positive photosensitive resin composition (PB-14) and a cured film (BK-14) thereof. The evaluation was performed in the same manner as in Example 1.

### Example 15

In the same manner as in Example 1, DB-4 was used as the type of the colored pigment dispersion liquid to be charged, P-4 was used as the alkaline soluble resin, 15.0 g of γ-butyrolactone was used as the organic solvent, and the amount of PGME was set at 810.0 g to obtain a positive photosensitive resin composition (PB-15) and a cured film (BK-15) thereof. The evaluation was performed in the same manner as in Example 1.

### Example 16

In the same manner as in Example 1, DB-4 was used as the type of the colored pigment dispersion liquid to be charged, P-4 was used as the alkaline soluble resin, 285.0 g of γ-butyrolactone was used as the organic solvent, and the amount of PGME was set at 540.0 g to obtain a positive photosensitive resin composition (PB-16) and a cured film (BK-16) thereof. The evaluation was performed in the same manner as in Example 1.

### Example 17

In the same manner as in Example 1, DB-4 was used as the type of the colored pigment dispersion liquid to be charged, P-4 was used as the alkaline soluble resin, 375.0 g of γ-butyrolactone was used as the organic solvent, and the amount of PGME was set at 450.0 g to obtain a positive photosensitive resin composition (PB-17) and a cured film (BK-17) thereof. The evaluation was performed in the same manner as in Example 1.

### Examples 18 to 21

In the same manner as in Example 1, DB-15 to DB-18 were respectively used as the colored pigment dispersion liquid to be charged to obtain positive photosensitive resin compositions (PB-18) to (PB-21) and cured films (BK-18) to (BK-21) thereof. The evaluation was performed in the same manner as in Example 1.

### Comparative Example 1

In the same manner as in Example 1, DB-9 was used as the type of the colored pigment dispersion liquid to be charged, and P-9 was used in place of the alkaline soluble resin P-1 to obtain a positive photosensitive resin composition (PB-22) and a cured film (BK-22) thereof. The evaluation was performed in the same manner as in Example 1.

### Comparative Example 2

In the same manner as in Example 1, DB-10 was used as the type of the colored pigment dispersion liquid to be charged, and P-10 was used as the alkaline soluble to obtain a positive photosensitive resin composition (PB-23) and a cured film (BK-23) thereof. The evaluation was performed in the same manner as in Example 1.

### Comparative Example 3

In the same manner as in Example 1, DB-19 was used as the type of the colored pigment dispersion liquid to be charged, and P-10 was used as the alkaline soluble resin to obtain a positive photosensitive resin composition (PB-24) and a cured film (BK-24) thereof. The evaluation was performed in the same manner as in Example 1. The results are shown in Table 3.

TABLE 2

| | | Positive photosensitive resin composition | | | | | | | | | | |
|---|---|---|---|---|---|---|---|---|---|---|---|---|
| | | | | | | | Component (C) | | | | | |
| | Photo- | | | | | | | Content of | | | | |
| | sensi- | | | | | | | component | | | | |
| | tive | | | | | | | (C-1) in | | | | |
| | resin | Pigment dispersion liquid | | | Component (B) | | | component | Com- | | Photo acid | |
| | compo- | | | Polymer | | Acid | Component | (C) | ponent | W_{C2}/ | generator | Surfac- |
| | sition | Dispersion | Colorant | dispersant | Type | equivalent | (C-1) | (% by mass) | (C-2) | W_{C1} | (D) | tant |
| Example 1 | PB-1 | DB-1 | ZrN-1 | — | P-1 | 220 g/mol | γ-Butyrolactone | 20% | PGME | 4.0 | D-1 | BYK333 |
| Example 2 | PB-2 | DB-2 | ZrN-1 | — | P-2 | 275 g/mol | γ-Butyrolactone | 20% | PGME | 4.0 | D-1 | BYK333 |
| Example 3 | PB-3 | DB-3 | ZrN-1 | — | P-3 | 329 g/mol | γ-Butyrolactone | 20% | PGME | 4.0 | D-1 | BYK333 |
| Example 4 | PB-4 | DB-4 | ZrN-1 | — | P-4 | 366 g/mol | γ-Butyrolactone | 20% | PGME | 4.0 | D-1 | BYK333 |
| Example 5 | PB-5 | DB-5 | ZrN-1 | — | P-5 | 411 g/mol | γ-Butyrolactone | 20% | PGME | 4.0 | D-1 | BYK333 |
| Example 6 | PB-6 | DB-6 | ZrN-1 | — | P-6 | 471 g/mol | γ-Butyrolactone | 20% | PGME | 4.0 | D-1 | BYK333 |
| Example 7 | PB-7 | DB-7 | ZrN-1 | — | P-7 | 341 g/mol | γ-Butyrolactone | 20% | PGME | 4.0 | D-1 | BYK333 |
| Example 8 | PB-8 | DB-8 | ZrN-1 | — | P-8 | 339 g/mol | γ-Butyrolactone | 20% | PGME | 4.0 | D-1 | BYK333 |
| Example 9 | PB-9 | DB-11 | ZrN-A1 | — | P-4 | 366 g/mol | γ-Butyrolactone | 20% | PGME | 4.0 | D-1 | BYK333 |
| Example 10 | PB-10 | DB-12 | ZrN-1 | — | P-4 | 366 g/mol | γ-Butyrolactone | 20% | PGME | 4.0 | D-1 | BYK333 |
| Example 11 | PB-11 | DB-4 | ZrN-1 | — | P-4 | 366 g/mol | γ-Butyrolactone | 20% | methyl | 4.0 | D-1 | BYK333 |
| | | | | | | | | | lactate | | | |
| Example 12 | PB-12 | DB-4 | ZrN-1 | — | P-4 | 366 g/mol | γ-Butyrolactone | 20% | ethyl | 4.0 | D-1 | BYK333 |
| | | | | | | | | | lactate | | | |
| Example 13 | PB-13 | DB-13 | ZrN-1 | — | P-4 | 366 g/mol | — | — | PGME | — | D-1 | BYK333 |
| Example 14 | PB-14 | DB-14 | ZrN-1 | — | P-4 | 366 g/mol | γ-Butyrolactone | 5% | PGME | 19.0 | D-1 | BYK333 |
| Example 15 | PB-15 | DB-4 | ZrN-1 | — | P-4 | 366 g/mol | γ-Butyrolactone | 10% | PGME | 9.0 | D-1 | BYK333 |
| Example 16 | PB-16 | DB-4 | ZrN-1 | — | P-4 | 366 g/mol | γ-Butyrolactone | 40% | PGME | 1.5 | D-1 | BYK333 |
| Example 17 | PB-17 | DB-4 | ZrN-1 | — | P-4 | 366 g/mol | γ-Butyrolactone | 50% | PGME | 1.0 | D-1 | BYK333 |
| Example 18 | PB-18 | DB-15 | ZrN-2 | — | P-4 | 366 g/mol | γ-Butyrolactone | 20% | PGME | 4.0 | D-1 | BYK333 |
| Example 19 | PB-19 | DB-16 | ZrN-2 | — | P-4 | 366 g/mol | γ-Butyrolactone | 20% | PGME | 4.0 | D-1 | BYK333 |
| Example 20 | PB-20 | DB-17 | ZrN-1 | — | P-4 | 366 g/mol | γ-Butyrolactone | 20% | PGME | 4.0 | D-1 | BYK333 |
| Example 21 | PB-21 | DB-18 | ZrN-1 | — | P-4 | 366 g/mol | γ-Butyrolactone | 20% | PGME | 4.0 | D-1 | BYK333 |
| Comparative | PB-22 | DB-9 | ZrN-1 | — | P-9 | 170 g/mol | γ-Butyrolactone | 20% | PGME | 4.0 | D-1 | BYK333 |
| Example 1 | | | | | | | | | | | | |
| Comparative | PB-23 | DB-10 | ZrN-1 | — | P-10 | 550 g/mol | γ-Butyrolactone | 20% | PGME | 4.0 | D-1 | BYK333 |
| Example 2 | | | | | | | | | | | | |
| Comparative | PB-24 | DB-19 | ZrN-1 | BYK-2200 | P-10 | 550 g/mol | γ-Butyrolactone | 20% | PGME | 4.0 | D-1 | BYK333 |
| Example 3 | | | | | | | | | | | | |

TABLE 3

| | | | | | | | Evaluation of photosensitivity | | | | | |
|---|---|---|---|---|---|---|---|---|---|---|---|---|
| | | Evaluation of dispersion stability | | | | | | | | | Amount of | |
| | | Viscosity/cP | | | | | | | | | developed | |
| | Photo- | Imme- | | | | | Sensitivity @OD = 1 | | | | film | |
| | sensitive | diately | After | | | Light- | Imme- | | After | | loss in | |
| | resin | after | 7 days | Viscosity | | shielding | diately | | 7 days | | unexposed | Residue |
| | compo- | prepar- | at room | change | Dispersion | property | after | Eval- | at room | Eval- | area | in |
| | sition | ation | temperature | rate | stability | OD/μm | preparation | uation | temperature | uation | @OD = 1 | opening |
| Example 1 | PB-1 | 4.81 | 4.80 | −0.2% | A | 0.9 | 60 mJ/cm² | A | 60 mJ/cm² | A | 0.68 μm | B |
| Example 2 | PB-2 | 4.77 | 4.79 | 0.4% | A | 0.9 | 70 mJ/cm² | A | 70 mJ/cm² | A | 0.52 μm | B |
| Example 3 | PB-3 | 4.65 | 4.63 | −0.4% | A | 0.9 | 80 mJ/cm² | A | 80 mJ/cm² | A | 0.36 μm | A |
| Example 4 | PB-4 | 4.54 | 4.48 | −1.3% | A | 0.9 | 80 mJ/cm² | A | 80 mJ/cm² | A | 0.30 μm | A |
| Example 5 | PB-5 | 4.44 | 4.55 | 2.5% | A | 0.9 | 80 mJ/cm² | A | 80 mJ/cm² | A | 0.27 μm | A |
| Example 6 | PB-6 | 4.12 | 4.38 | 6.3% | B | 0.9 | 100 mJ/cm² | B | 100 mJ/cm³ | B | 0.25 μm | A |
| Example 7 | PB-7 | 4.34 | 4.79 | 10.4% | C | 0.9 | 100 mJ/cm² | B | 100 mJ/cm³ | B | 0.28 μm | A |
| Example 8 | PB-8 | 3.95 | 4.65 | 17.7% | C | 0.9 | 100 mJ/cm² | B | 100 mJ/cm³ | B | 0.43 μm | A |
| Example 9 | PB-9 | 4.34 | 4.28 | −1.4% | A | 1.1 | 60 mJ/cm² | A | 60 mJ/cm² | A | 0.33 μm | A |
| Example 10 | PB-10 | 5.28 | 5.89 | 11.6% | C | 0.9 | 80 mJ/cm² | A | 80 mJ/cm² | A | 0.41 μm | A |
| Example 11 | PB-11 | 5.11 | 5.19 | 1.6% | A | 0.9 | 80 mJ/cm² | A | 80 mJ/cm² | A | 0.40 μm | A |
| Example 12 | PB-12 | 5.04 | 5.21 | 3.4% | A | 0.9 | 80 mJ/cm² | A | 80 mJ/cm² | A | 0.85 μm | C |
| Example 13 | PB-13 | 4.19 | 5.62 | 34.1% | D | 0.9 | 80 mJ/cm² | A | 80 mJ/cm² | A | 0.26 μm | A |
| Example 14 | PB-14 | 4.38 | 5.31 | 21.2% | D | 0.9 | 80 mJ/cm² | A | 80 mJ/cm² | A | 0.28 μm | A |
| Example 15 | PB-15 | 4.42 | 4.37 | −1.1% | A | 0.9 | 80 mJ/cm² | A | 80 mJ/cm² | A | 0.31 μm | A |
| Example 16 | PB-16 | 4.59 | 4.52 | −1.5% | A | 0.9 | 80 mJ/cm² | A | 80 mJ/cm² | A | 0.38 μm | A |
| Example 17 | PB-17 | 4.68 | 4.63 | −1.1% | A | 0.9 | 80 mJ/cm² | A | 80 mJ/cm² | A | 1.02 μm | D |
| Example 18 | PB-18 | 6.52 | 6.48 | −0.6% | A | 0.5 | 60 mJ/cm² | A | 60 mJ/cm² | A | 0.22 μm | A |
| Example 19 | PB-19 | 5.56 | 5.48 | −1.4% | A | 0.8 | 80 mJ/cm² | A | 80 mJ/cm² | A | 0.25 μm | A |
| Example 20 | PB-20 | 4.12 | 4.16 | 1.0% | A | 0.9 | 80 mJ/cm² | A | 80 mJ/cm² | A | 0.45 μm | A |
| Example 21 | PB-21 | 3.88 | 3.90 | 0.5% | A | 0.9 | 100 mJ/cm² | B | 100 mJ/cm² | B | 0.75 μm | C |
| Comparative | PB-23 | 4.86 | 4.90 | 0.8% | A | 0.90 | No pattern (the unexposed area was completely dissolved) | | | | | |
| Example 1 | | | | | | | | | | | | |
| Comparative | PB-24 | 4.55 | 8.11 | 78.2% | E | 0.90 | 100 mJ/cm² | B | 200 mJ/cm² | C | 0.31 μm | A |
| Example 2 | | | | | | | | | | | | |
| Comparative | PB-25 | 4.32 | 4.38 | 1.4% | A | 0.90 | 200 mJ/cm² | C | 500 mJ/cm² | D | 0.40 μm | A |
| Example 3 | | | | | | | | | | | | |

The photosensitive resin compositions of Examples exhibited excellent storage stability, small change in viscosity and small change in sensitivity after 7 days at room temperature, and small amount of film loss in the unexposed area, so that it is possible to form a pattern with less residue in the opening due to adhesion of an eluate from the unexposed area. Meanwhile, the photosensitive resin compositions of Comparative Examples exhibited poor storage stability, and a tendency to increase the viscosity and decrease the sensitivity. In Comparative Example 2, developed film loss in the unexposed area was large, thus failing to obtain a pattern with less residue in the opening.

Subsequently, the method for fabricating an organic EL display device using the photosensitive resin composition of the present invention and the evaluation results will be described.

### Production Example 25 Preparation of Negative Photosensitive Resin Composition NB-1

To 93.8 g of a colored pigment dispersion liquid (DB-20), 127.3 g of a 35% by weight PGMEA solution of an alkaline soluble resin (P-11), 31.0 g of dipentaerythritol hexaacrylate (manufactured by Nippon Kayaku Co., Ltd.) as a polyfunctional monomer, 5.4 g of “ADEKA ARKLS” (registered trademark) NCI-831 (manufactured by ADEKA Corporation) as a photopolymerization initiator, and a solution prepared by dissolving 3.0 g of a 10% by weight PGMEA solution of a silicone-based surfactant “BYK” (registered trademark) 333 (manufactured by BYK-Chemie GmbH) as a surfactant in 739.5 g of PGMEA were added to obtain a negative photosensitive black resin composition NB-1 having a total solid content concentration of 10% by weight and (A) zirconia compound particles/(B) alkaline soluble resin (weight ratio) of 15/85.

### Production Example 26 Preparation of Negative Photosensitive Resin Composition NB-2

To 143.8 g of a colored pigment dispersion liquid (DB-20), 110.1 g of a 35% by weight PGMEA solution of an alkaline soluble resin (P-11), 27.6 g of dipentaerythritol hexaacrylate (manufactured by Nippon Kayaku Co., Ltd.) as a polyfunctional monomer, 4.8 g of “ADEKA ARKLS” (registered trademark) NCI-831 (manufactured by ADEKA Corporation) as a photopolymerization initiator, and a solution prepared by dissolving 3.0 g of a 10% by weight PGMEA solution of a silicone-based surfactant “BYK” (registered trademark) 333 (manufactured by BYK-Chemie GmbH) as a surfactant in 710.8 g of PGMEA was added to obtain a negative photosensitive black resin composition NB-2 having a total solid content concentration of 10% by weight and (A) zirconia compound particles/(B) alkaline soluble resin (weight ratio) of 23/77.

### Production Example 27 Preparation of Negative Photosensitive Resin Composition NB-3

To 125.0 g of a colored pigment dispersion liquid (DB-20), 116.5 g of a 35% by weight PGMEA solution of an alkaline soluble resin (P-11), 28.9 g of dipentaerythritol hexaacrylate (manufactured by Nippon Kayaku Co., Ltd.) as a polyfunctional monomer, 5.1 g of “ADEKA ARKLS” (registered trademark) NCI-831 (manufactured by ADEKA Corporation) as a photopolymerization initiator, and a solution prepared by dissolving 3.0 g of a 10% by weight PGMEA solution of a silicone-based surfactant “BYK” (registered trademark) 333 (manufactured by BYK-Chemie GmbH) as a surfactant in 721.6 g of PGMEA were added to obtain a negative photosensitive black resin composition NB-3 having a total solid content concentration of 10% by weight and (A) zirconia compound particles/(B) alkaline soluble resin (weight ratio) of 20/80.

### Production Example 28 Preparation of Negative Photosensitive Resin Composition NB-4

To 62.5 g of a colored pigment dispersion liquid (DB-20), 138.1 g of a 35% by weight PGMEA solution of an alkaline soluble resin (P-11), 33.1 g of dipentaerythritol hexaacrylate (manufactured by Nippon Kayaku Co., Ltd.) as a polyfunctional monomer, 5.8 g of “ADEKA ARKLS” (registered trademark) NCI-831 (manufactured by ADEKA Corporation) as a photopolymerization initiator, and a solution prepared by dissolving 3.0 g of a 10% by weight PGMEA solution of a silicone-based surfactant “BYK” (registered trademark) 333 (manufactured by BYK-Chemie GmbH) as a surfactant in 757.5 g of PGMEA were added to obtain a negative photosensitive black resin composition NB-4 having a total solid content concentration of 10% by weight and (A) zirconia compound particles/(B) alkaline soluble resin (weight ratio) of 10/90.

### Production Example 29 Preparation of Negative Photosensitive Resin Composition NB-5

To 43.8 g of a colored pigment dispersion liquid (DB-20), 144.6 g of a 35% by weight PGMEA solution of an alkaline soluble resin (P-11), 34.3 g of dipentaerythritol hexaacrylate (manufactured by Nippon Kayaku Co., Ltd.) as a polyfunctional monomer, 6.0 g of “ADEKA ARKLS” (registered trademark) NCI-831 (manufactured by ADEKA Corporation) as a photopolymerization initiator, and a solution prepared by dissolving 3.0 g of a 10% by weight PGMEA solution of a silicone-based surfactant “BYK” (registered trademark) 333 (manufactured by BYK-Chemie GmbH) as a surfactant in 768.3 g of PGMEA were added to obtain a negative photosensitive black resin composition NB-5 having a total solid content concentration of 10% by weight and (A) zirconia compound particles/(B) alkaline soluble resin (weight ratio) of 10/90.

### Production Examples 30 to 33 Preparation of Negative Photosensitive Resin Compositions NB-6 to NB-9

In the same manner as in Production Example 25, DB-21 to DB-24 were respectively used as the colored pigment dispersion liquid to be used to obtain negative photosensitive black resin compositions NB-6 to NB-9 each having a total solid content concentration of 10% by weight and (A) zirconia compound particles/(B) alkaline soluble resin (weight ratio) of 15/85.

### Example 22

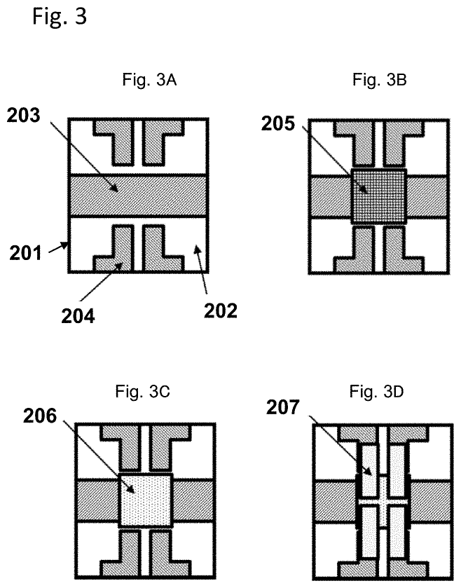

The procedure for fabrication of an organic EL display device will be described with reference to FIG. 3A to FIG. 3D. First, a positive photosensitive resin composition PC-1 (photosensitive resin composition R-4 mentioned in column [0310] of JP 2020-004717 A) was applied on the whole surface of an alkaline-free glass substrate 201 in size of 38 mm×46 mm by spin coating using a spin coater (MS-A100; manufactured by Mikasa Co., Ltd.) and then prebaked at 100° C. for 120 seconds using a hot plate (SCW-636; manufactured by Dainippon Screen Mfg. Co., Ltd.) to fabricate a prebaked film having a thickness of 3.0 μm.

Using a double-sided alignment single-sided exposure apparatus (Mask Aligner PEM-6M; manufactured by Union Optical Co., Ltd.), the prebaked film thus fabricated was exposed over the whole surface with i-rays, h-rays and g-rays of an ultrahigh-pressure mercury lamp through a photomask having a predetermined pattern, developed with an aqueous 2.38% by mass TMAH solution for 60 seconds using a compact development apparatus for photolithography (AC3000; manufactured by TAKIZAWA SANGYO K.K.) and then rinsed with water for 30 seconds. The substrate was thermally cured at 230° C. using a high-temperature inert gas oven (INH-9CD-S, manufactured by Koyo Thermo System Co., Ltd.) to form a planarization layer 202 having a thickness of about 2.0 μm.

Subsequently, an ITO transparent electric conductive film having a thickness of 100 nm was formed by a sputtering method and etched as a first electrode 203 to form a transparent electrode. Auxiliary electrodes 204 for taking out the second electrodes were also formed at the same time (FIG. 3A). The obtained substrate was washed with ultrasonic wave for 10 minutes using Semico Clean 56 (trade name, manufactured by Furuuchi Chemical Co., Ltd.) and then washed with ultrapure water. Subsequently, the positive photosensitive resin composition PB-1 was applied on the whole surface of this substrate by spin coating at an arbitrary number of rotations using a spin coater (MS-A100; manufactured by Mikasa Co., Ltd.) and then prebaked at 100° C. for 120 seconds using a hot plate (SCW-636; manufactured by DAINIPPON SCREEN MFG. CO., LTD.) to form a prebaked film having a film thickness of 3.0 μm.

The formed prebaked film was subjected to patterning exposure to i-rays, h-rays and g-rays of an ultra-high pressure mercury lamp through a photomask having a predetermined pattern using a double-side alignment and one-side exposure apparatus (Mask Aligner PEM-6M, manufactured by Union Optical Co., LTD.), and then developed with an aqueous 2.38% by mass TMAH solution for 60 seconds using a compact development apparatus for photolithography (AC3000; manufactured by TAKIZAWA SANGYO K.K.) and rinsed with water for 30 seconds. Thus, a pixel division layer 205, in which the openings having a width of 50 μm and a length of 260 μm were arranged in a pitch of 155 μm in a width direction and an interval of 465 μm in a length direction and each opening had a shape exposing the first electrode, was formed only in the specific effective area in the substrate (FIG. 3B). The opening finally becomes a light emitting pixel of the organic EL display device. The effective area of the substrate (the display area) was determined to be a 16 mm square and the pixel division layer 205 having an opening ratio of 18% was provided. The pixel division layer 205 was formed in a thickness of about 2.0 μm.

The obtained substrate was subjected to a nitrogen plasma treatment and then a light emitting pixel 206 including a light emitting layer was formed by vacuum evaporation method (FIG. 3C). The degree of vacuum during the evaporation was 1×10⁻³ Pa or less and the substrate was rotated relative to the evaporation source during the evaporation. First, the compound (HT-1) was deposited in a thickness of 10 nm as the hole injection layer and the compound was deposited in a thickness of 50 nm as the hole transport layer (HT-2) by evaporation. Subsequently, the compound (GH-1) as the host material and the compound (GD-1) as the dopant material were deposited by evaporation as the light emitting layer in a thickness of 40 nm so that the doping concentration was 10%. Subsequently, the compound (ET-1) as the electron transport material and the compound (LiQ) were laminated in a thickness of 40 nm in a volume ratio of 1:1 to obtain a light emitting pixel 206. The structures of the compounds used in the light emitting pixel are shown below.

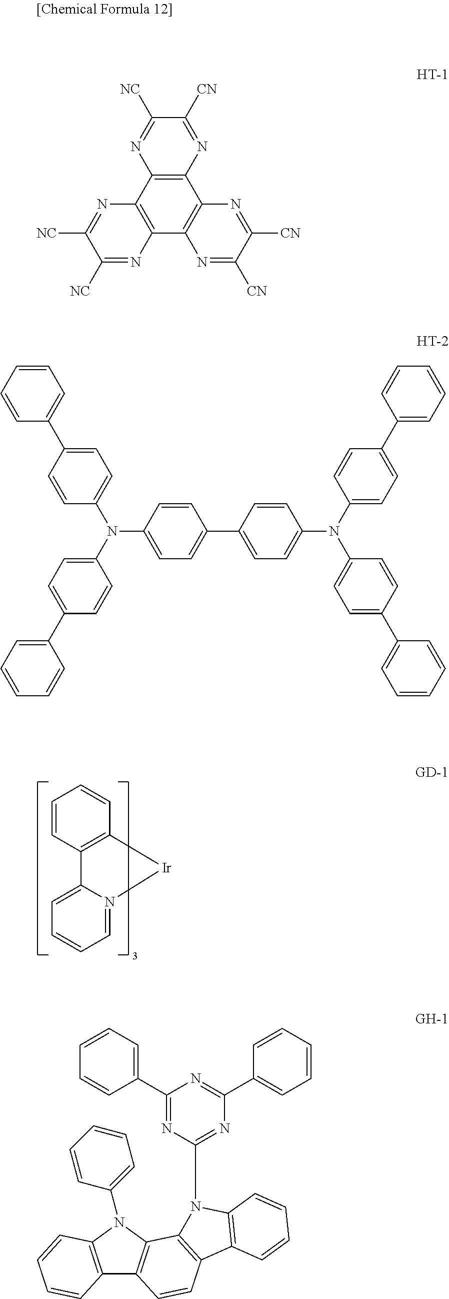

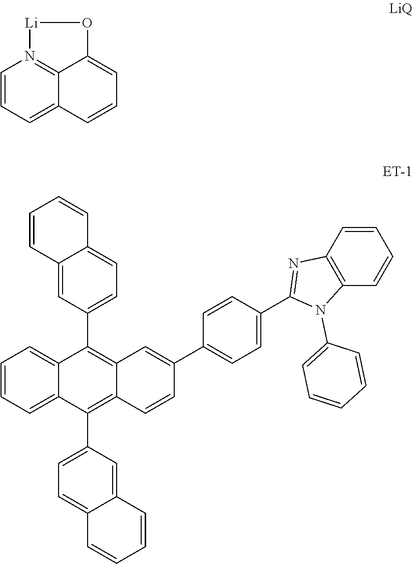

Subsequently, the compound (LiQ) was deposited in a thickness of 2 nm on the light emitting pixel 206, and then Mg and Ag were deposited in a thickness of 100 nm at a volume ratio of 10:1 to form a second electrode 207 (FIG. 3D). Finally, a color filter substrate (CF-1) having a black matrix having an OD value of 4.5 was fabricated by the method mentioned in Document (JP 2019-148619 A; Example 1), and sealing was performed by bonding to the second electrode 207 with an epoxy resin-based adhesive to complete a top-emission organic EL display device having a square shape with a side of 5 mm. The color filter substrate was fabricated so that openings having a width of 50 μm and a length of 260 μm were arranged at a pitch of 155 μm in the width direction and a pitch of 465 μm in the length direction, and colored pixels were arranged in the openings. Four such organic EL display devices were fabricated on one substrate. The thickness as used herein is a display value in a crystal oscillation type thickness monitor.

### Example 23

In the same manner as in Example 22, the planarization layer was formed using PB-1 and the pixel division layer was formed using PC-1, respectively, to fabricate an organic EL display device.

### Examples 24 to 39

In the same manner as in Example 22, the pixel division layer was formed using PB-2 to PB-17, respectively, to fabricate an organic EL display device.

### Examples 40 to 44

In the same manner as in Example 22, the pixel division layer was formed using NB-1 to NB-5 through a negative photomask for formation of the pixel division layer to fabricate an organic EL display device.

### Examples 45 to 46

In the same manner as in Example 23, a color filter having a black matrix substrate (CF-2) having an OD value of 2.5 and a color filter having a black matrix substrate (CF-3) having an OD value of 1.5 were respectively used in place of CF-1 to fabricate an organic EL display device.

### Examples 47 to 51

In the same manner as in Example 22, the thickness of NB-1 used for the pixel division layer was as shown in Table 4, an alkaline-free glass substrate was used in place of the color filter, and sealing was performed by bonding with an epoxy resin-based adhesive to fabricate an organic EL display device.

### Examples 52 to 53

In the same manner as in Example 22, NB-7 and NB-8 were respectively used as the photosensitive resin composition used for the pixel division layer, an alkaline-free glass substrate was used in place of the color filter, and sealing was performed by bonding using an epoxy resin-based adhesive to fabricate an organic EL display device.

### Comparative Examples 4 to 5

In the same manner as in Example 22, NB-6 and NB-9 were used as the photosensitive resin composition used for the pixel division layer, an alkaline-free glass substrate was used in place of the color filter, and sealing was performed by bonding using an epoxy resin-based adhesive to fabricate an organic EL display device.

### Comparative Example 6

In the same manner as in Example 22, PC-1 was used as the photosensitive resin composition used for the pixel division layer to fabricate an organic EL display device.

TABLE 4

| | | Negative photosensitive resin composition | | | | | | | |
|---|---|---|---|---|---|---|---|---|---|
| | Photosensitive | Pigment dispersion liquid | | | Alkali | Monomer | | Photopoly- | |
| | resin | | | Polymer | soluble resin | Component | Pigment/resin | merization | |
| | composition | Dispersion | Colorant | dispersant | Type | (C-1) | ratio | initiator | Surfactant |
| Production | NB-1 | DB-20 | ZrN-1 | BYK-2200 | P-11 | DPHA | 15/85 | NCI-831 | BYK333 |
| Example 25 | | | | | | | | | |
| Production | NB-2 | DB-20 | ZrN-1 | BYK-2200 | P-11 | DPHA | 23/77 | NCI-831 | BYK333 |
| Example 26 | | | | | | | | | |
| Production | NB-3 | DB-20 | ZrN-1 | BYK-2200 | P-11 | DPHA | 20/80 | NCI-831 | BYK333 |
| Example 27 | | | | | | | | | |
| Production | NB-4 | DB-20 | ZrN-1 | BYK-2200 | P-11 | DPHA | 10/90 | NCI-831 | BYK333 |
| Example 28 | | | | | | | | | |
| Production | NB-5 | DB-20 | ZrN-1 | BYK-2200 | P-11 | DPHA | 7/93 | NCI-831 | BYK333 |
| Example 29 | | | | | | | | | |
| Production | NB-6 | DB-21 | ZrN-2 | BYK-2200 | P-11 | DPHA | 15/85 | NCI-831 | BYK333 |
| Example 30 | | | | | | | | | |
| Production | NB-7 | DB-22 | ZrN-2 | BYK-2200 | P-11 | DPHA | 15/85 | NCI-831 | BYK333 |
| Example 31 | | | | | | | | | |
| Production | NB-8 | DB-23 | ZrN-1 | BYK-2200 | P-11 | DPHA | 15/85 | NCI-831 | BYK333 |
| Example 32 | | | | | | | | | |
| Production | NB-9 | DB-21 | ZrN-1 | BYK-2200 | P-11 | DPHA | 15/85 | NCI-831 | BYK333 |
| Example 33 | | | | | | | | | |

TABLE 5

| | | | | | | | | | Crystallite | | | | | |
|---|---|---|---|---|---|---|---|---|---|---|---|---|---|---|
| | Planarization layer | | | Pixel division layer | | | Color filter | | size | | | Device in | | |
| | | Film | OD | | Film | | With/ | | (in cured | OD value | | off-pixel | Dark- | Reli- |
| | Material | thickness | value | Material | thickness | OD | Without | OD | film) | difference | Visibility | state | spots | ability |
| Example 22 | PC-1 | 2.0 | 0 | PB-1 | 2.0 | 1.8 | CF-1 | 4.5 | 15 nm | 2.7 | B | A | A | A |
| Example 23 | PB-1 | 2.0 | 1.8 | PC-1 | 2.0 | 0 | CF-1 | 4.5 | 15 nm | 2.7 | B | A | A | A |
| Example 24 | PC-1 | 2.0 | 0 | PB-2 | 2.0 | 1.8 | CF-1 | 4.5 | 15 nm | 2.7 | B | A | A | A |
| Example 25 | PC-1 | 2.0 | 0 | PB-3 | 2.0 | 1.8 | CF-1 | 4.5 | 15 nm | 2.7 | B | A | A | A |
| Example 25 | PC-1 | 2.0 | 0 | PB-4 | 2.0 | 1.8 | CF-1 | 4.5 | 15 nm | 2.7 | B | A | A | A |
| Example 27 | PC-1 | 2.0 | 0 | PB-5 | 2.0 | 1 8 | CF-1 | 4.5 | 15 nm | 2.7 | B | A | A | A |
| Example 28 | PC-1 | 2.0 | 0 | PB-6 | 2.0 | 1.8 | CF-1 | 4.5 | 15 nm | 2.7 | B | A | A | A |
| Example 29 | PC-1 | 2.0 | 0 | PB-7 | 2.0 | 1.8 | CF-1 | 4.5 | 15 nm | 2.7 | B | A | B | A |
| Example 30 | PC-1 | 2.0 | 0 | PB-8 | 2.0 | 1.8 | CF-1 | 4.5 | 15 nm | 2.7 | B | A | B | B |
| Example 31 | PC-1 | 2.0 | 0 | PB-9 | 2.0 | 2.2 | CF-1 | 4.5 | 15 nm | 2.3 | A | A | A | A |
| Example 32 | PC-1 | 2.0 | 0 | PB-10 | 2.0 | 1.8 | CF-1 | 4.5 | 15 nm | 2.7 | B | A | B | A |
| Example 33 | PC-1 | 2.0 | 0 | PB-11 | 2.0 | 1.8 | CF-1 | 4.5 | 15 nm | 2.7 | B | A | A | A |
| Example 34 | PC-1 | 2.0 | 0 | PB-12 | 2.0 | 1.8 | CF-1 | 4.5 | 15 nm | 2.7 | B | A | B | A |
| Example 35 | PC-1 | 2.0 | 0 | PB-13 | 2.0 | 1.8 | CF-1 | 4.5 | 15 nm | 2.7 | B | B | C | A |
| Example 36 | PC-1 | 2.0 | 0 | PB-14 | 2.0 | 1.8 | CF-1 | 4.5 | 15 nm | 2.7 | B | B | B | A |
| Example 37 | PC-1 | 2.0 | 0 | PB-15 | 2.0 | 1.8 | CF-1 | 4.5 | 15 nm | 2.7 | B | A | A | A |
| Example 38 | PC-1 | 2.0 | 0 | PB-16 | 2.0 | 1.8 | CF-1 | 4.5 | 15 nm | 2.7 | B | A | A | A |
| Example 39 | PC-1 | 2.0 | 0 | PB-17 | 2.0 | 1.8 | CF-1 | 4.5 | 15 nm | 2.7 | B | B | C | A |
| Example 40 | PC-1 | 2.0 | 0 | NB-1 | 2.0 | 1.8 | CF-1 | 4.5 | 15 nm | 2.7 | B | B | D | C |
| Example 41 | PC-1 | 2.0 | 0 | NB-2 | 2.0 | 2.7 | CF-1 | 4.5 | 15 nm | 1.8 | B | C | D | C |
| Example 42 | PC-1 | 2.0 | 0 | NB-3 | 2.0 | 2.3 | CF-1 | 4.5 | 15 nm | 2.2 | B | B | D | C |
| Example 43 | PC-1 | 2.0 | 0 | NB-4 | 2.0 | 1.2 | CF-1 | 4.5 | 15 nm | 3.3 | B | B | D | C |
| Example 44 | PC-1 | 2.0 | 0 | NB-5 | 2.0 | 0.8 | CF-1 | 4.5 | 15 nm | 3.7 | B | C | D | C |
| Example 45 | PC-1 | 2.0 | 0 | NB-1 | 2.0 | 1.8 | CF-2 | 2.5 | 15 nm | 0.7 | C | B | D | C |
| Example 46 | PC-1 | 2.0 | 0 | NB-1 | 2.0 | 1.8 | CF-3 | 1.5 | 15 nm | −0.3 | D | B | D | C |
| Example 47 | PC-1 | 2.0 | 0 | NB-1 | 2.0 | 1.8 | Without | — | 15 nm | — | E | B | D | D |
| Example 48 | PC-1 | 2.0 | 0 | NB-1 | 1.2 | 1.1 | Without | — | 15 nm | — | E | C | D | D |
| Example 49 | PC-1 | 2.0 | 0 | NB-1 | 1.7 | 1.5 | Without | — | 15 nm | — | E | B | D | D |
| Example 50 | PC-1 | 2.0 | 0 | NB-1 | 2.8 | 2.5 | Without | — | 15 nm | — | E | B | D | D |
| Example 51 | PC-1 | 2.0 | 0 | NB-1 | 3.2 | 2.9 | Without | — | 15 nm | — | E | C | D | D |
| Example 52 | PC-1 | 2.0 | 0 | NB-7 | 1.2 | 1 | Without | — | 8 nm | — | E | C | D | C |
| Example 53 | PC-1 | 2.0 | 0 | NB-8 | 1.2 | 1.1 | Without | — | 20 nm | — | E | C | D | C |
| Comparative | PC-1 | 2.0 | 0 | NB-6 | 1.2 | 0.6 | Without | — | 4 nm | — | F | C | D | E |
| Example 4 | | | | | | | | | | | | | | |
| Comparative | PC-1 | 2.0 | 0 | NB-9 | 1.2 | 1.1 | Without | — | 25 nm | — | E | D | E | D |
| Example 5 | | | | | | | | | | | | | | |
| Comparative | PC-1 | 2.0 | 0 | PC-1 | 2.0 | 0 | CF-1 | 4.5 | — | — | F | A | A | E |
| Example 6 | | | | | | | | | | | | | | |

The organic EL display devices of Examples exhibited small difference in luminance with and without irradiation with external light, excellent visibility, low frequency of occurrence of device in off-pixel state and darkspots, and excellent long-term light emission reliability. Meanwhile, the organic EL display devices mentioned in Comparative Example exert small effect of reducing external light reflection, and they are inferior in visibility and long-term reliability or are likely to cause a short circuit due to a large crystallite size of zirconium nitride particles which are coloring pigments, thus resulting in high frequency of occurrence of device in off-pixel state and darkspots.

### REFERENCE SIGNS LIST

1 TFT
2 Wire line
3 TFT insulating layer
4 Planarization layer
5 ITO
6 Substrate
7 Contact hole
8 Pixel division layer
101 Glass substrate
102 TFT
103 Planarization layer
104 First electrode
105a Prebaked film
105b Pixel division layer
106 Mask
107 Active actinic rays
108 Light emitting pixel
109 Second electrode
110 Cured film for planarization
111 Color filter or cover glass
201 Glass substrate
202 Planarization layer
203 First electrode
204 Auxiliary electrode
205 Pixel division layer
206 Light emitting pixel
207 Second electrode

1. An organic EL display device comprising a substrate, and a planarization layer, a first electrode, a pixel division layer, a light emitting pixel and a second electrode formed on the substrate, wherein the planarization layer and/or the pixel division layer contain(s) zirconium nitride particles (A), and a crystallite size of the zirconium nitride particles (A) determined from a half width of a peak derived from a (111) plane in an X-ray diffraction spectrum using a CuKα ray as an X-ray source is 5 nm or more 20 nm or less.

2. The organic EL display device according to claim 1, wherein each thickness of the planarization layer and/or the pixel division layer is 1.5 μm or more and 3.0 μm or less.

3. The organic EL display device according to claim 1, wherein the organic EL display device further comprises a color filter having a black matrix, and an OD value of the black matrix is higher than an OD value of the planarization layer containing the zirconium nitride particles (A) and/or an OD value of the pixel division layer containing the zirconium nitride particles (A).

4. The organic EL display device according to claim 3, wherein a difference in the OD value of the black matrix and the OD value of the planarization layer containing the zirconium nitride particles (A) and/or the pixel division layer containing the zirconium nitride particles (A) is 2.0 or more and 3.5 or less.

5. The organic EL display device according to claim 1, wherein the planarization layer and/or the pixel division layer contains a compound having a cyclic imide structure and a compound having an indene structure.

6. The organic EL display device according to claim 1, wherein the zirconium nitride particles (A) contain particles of a composite nitride of a zirconium atom and a metal atom other than the zirconium atom.

7. The organic EL display device according to claim 1, wherein the planarization layer and/or the pixel division layer is/are cured film(s) obtained by curing a photosensitive resin composition, the photosensitive resin composition contains the zirconium nitride particles (A), an alkaline soluble resin (B) including a repeating structural unit represented by general formula (1) shown below and/or a repeating structural unit represented by general formula (2) shown below, an organic solvent (C) and a photoacid generator (D), and an acid equivalent of the alkaline soluble resin (B) is 200 g/mol or more and 500 g/mol or less: 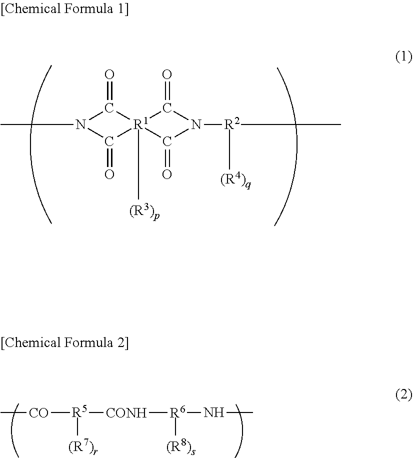
wherein, in general formula (1), R¹ represents a tetra- to decavalent organic group having 5 to 40 carbon atoms, R² represents a di- to octavalent organic group having 5 to 40 carbon atoms, R³ and R⁴ each independently represent a hydroxyl group, a carboxy group, a sulfonic acid group or a thiol group; and p and q represent an integer of 0 to 6 and p+q>0; and
wherein, in general formula (2), R⁵ represents a di- to octavalent organic group having 5 to 40 carbon atoms, R⁶ represents a di- to octavalent organic group having 5 to 40 carbon atoms; R⁷ and R⁸ each independently represent a hydroxyl group, a sulfonic acid group, a thiol group or COOR⁹; R⁹ represents a hydrogen atom or a monovalent hydrocarbon group having 1 to 20 carbon atoms; and r and s represent an integer of 0 to 6 and r+s>0.

8. A photosensitive resin composition comprising zirconium nitride particles (A), an alkaline soluble resin (B) including a repeating structural unit represented by general formula (1) shown below and/or a repeating structural unit represented by general formula (2) shown below, an organic solvent (C) and a photoacid generator (D), wherein an acid equivalent of the alkaline soluble resin (B) is 200 g/mol or more and 500 g/mol or less: 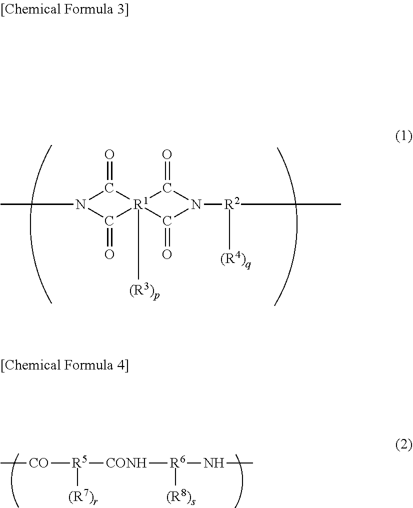
wherein, in general formula (1), R¹ represents a tetra- to decavalent organic group having 5 to 40 carbon atoms, R² represents a di- to octavalent organic group having 5 to 40 carbon atoms; R³ and R⁴ each independently represent a hydroxyl group, a carboxy group, a sulfonic acid group or a thiol group; and p and q represent an integer of 0 to 6 and p+q>0; and
wherein, in general formula (2), R⁵ represents a di- to octavalent organic group having 5 to 40 carbon atoms, R⁶ represents a di- to octavalent organic group having 5 to 40 carbon atoms; R⁷ and R⁸ each independently represent a hydroxyl group, a sulfonic acid group, a thiol group or COOR⁹; R⁹ represents a hydrogen atom or a monovalent hydrocarbon group having 1 to 20 carbon atoms; and r and s represent an integer of 0 to 6 and r+s>0.

9. The photosensitive resin composition according to claim 8, wherein a crystallite size of the zirconium nitride particles (A) in the cured film determined from a half width of a peak derived from a (111) plane in an X-ray diffraction spectrum using a CuKα ray of the zirconium nitride particles (A) in the photosensitive resin composition as an X-ray source is 5 nm or more 20 nm or less.

10. The photosensitive resin composition according to claim 8, wherein the zirconium nitride particles (A) contain particles of a composite nitride of a zirconium atom and a metal atom other than the zirconium atom.

11. The photosensitive resin composition according to claim 8, wherein the alkaline soluble resin (B) has a carboxy group.

12. The photosensitive resin composition according to claim 8, wherein the organic solvent (C) contains a cyclic ester solvent (C-1) having a boiling point under atmospheric pressure of 150° C. or higher and an organic solvent (C-2) having a boiling point under atmospheric pressure of lower than 150° C., and the content of the cyclic ester solvent (C-1) having a boiling point under atmospheric pressure of 150° C. or higher in 100% by mass of the organic solvent (C) is 10% by mass or more and 40% by mass or less.

13. The photosensitive resin composition according to claim 12, wherein the cyclic ester solvent (C-1) having a boiling point under atmospheric pressure of 150° C. or higher contains at least γ-butyrolactone.

14. The photosensitive resin composition according to claim 12, wherein the organic solvent (C-2) contains at least propylene glycol monomethyl ether and/or methyl lactate.

15. The photosensitive resin composition according to claim 12, wherein a mass ratio W_{c2}/W_{c1} of the mass W_{c1} of the cyclic ester solvent (C-1) having a boiling point under atmospheric pressure of 150° C. or higher to the mass W_{C2} of the organic solvent (C-2) in the organic solvent (C) is 1.5 to 9.0.
